(19) United States
(12) Patent Application Publication
(10) Pub. No.: US 2024/0240319 A1
(43) Pub. Date: Jul. 18, 2024

(54) FILM DEPOSITION APPARATUS AND FILM DEPOSITION METHOD

(71) Applicant: CV Research Corporation, Funabashi-shi, Chiba (JP)

(72) Inventor: Hiroshi KAWAURA, Chiba (JP)

(21) Appl. No.: 18/562,478

(22) PCT Filed: Feb. 6, 2023
(86) PCT No.: PCT/JP2023/003837

§ 371 Date: Nov. 20, 2023

(30) Foreign Application Priority Data
Feb. 10, 2022 (JP) 2022-019265
May 9, 2022 (JP) 2022-077039
Sep. 7, 2022 (JP) 2022-142182

(51) Int. Cl. C23C 16/458; C23C 16/44; C23C 16/455; C30B 25/12; C30B 25/14

(52) U.S. Cl. CPC C23C 16/4584; C23C 16/4412; C23C 16/45544; C23C 16/45563; C30B 25/12; C30B 25/14

(57) ABSTRACT

A film deposition apparatus having a plurality of susceptors, each of which has spot facings as a substrate mounting surface on a slope. The susceptors are arranged side by side horizontally and radially on a susceptor holder in a doughnut-shaped concave space inside a reactor. Gas supply tubes are provided on a lid in the circumferential direction in the following order: a purge gas supply tube, a precursor-containing gas supply tube, a purge gas supply tube and an oxidant-containing gas supply tube. Gases supplied to the reactor from gas outlet holes pass through a V-shaped groove space between the two susceptors and are exhausted from the bottom of the reactor. ALD deposition is performed by rotating the susceptor holder in the circumferential direction.

### FIELD OF INVENTION

This invention relates to film deposition apparatuses and methods used for manufacturing electronic devices such as semiconductors, flat panel displays, solar cells and light-emitting diodes, especially to film deposition apparatuses and methods using atomic layer deposition (ALD), epitaxial growth or chemical vapor deposition (CVD).

### BACKGROUND OF INVENTION

Deposition technologies using ALD, epitaxial growth or CVD are widely used for manufacturing electronic devices such as semiconductors, flat panel displays, solar cells and light-emitting diodes. In recent years, in particular, the double patterning technology that makes it possible to form extremely fine patterns without using very expensive extreme ultraviolet (EUV) lithography equipment has been developed, with ALD attracting attention as a key technology for this purpose. This is a technology to deposit a silicon or metal oxide film with a thickness of approximately 10-20 nm on a patterned organic resist film by a film deposition method with good uniformity and step coverage at a temperature of approximately 200° C. or lower to prevent degradation of the resist film. ALD technology is also being used in many other processes, including high-k/metal gate formation, top and bottom electrode formation for DRAM capacitors using TiN or Ru, gate electrode sidewall formation using SiN and barrier seed formation in contact holes and through holes, as well as high-k dielectric and charge trap film formation for NAND flash memory. ALD technology is also used in the formation of ITO and passivation films for flat panel displays, LEDs and solar cells.

In conventional ALD, single-wafer and batch types (see, for example, Patent document 1) are widely known, but the low processing speed (number of substrates that can be processed per unit time) is often a problem, prompting various efforts to date (see, for example, Patent document 2). As one of the inventions, a rotating semi-batch ALD apparatus was developed. In the rotating semi-batch ALD apparatus, a cylindrical vacuum vessel is divided into a total of four fan-shaped subchambers consisting of two reaction gas chambers and two purge gas chambers located between the reaction gas chambers, a reaction gas supply means is provided above the center of each subchamber, and a gas exhaust section is provided below the two purge gas chambers. By rotating a disk-shaped table, multiple substrates to be processed on the table pass through each sub-chamber to perform ALD deposition (see, for example, Patent document 3).

An improved rotating semi-batch ALD apparatus with a gas curtain was developed. In the gas curtain-type rotating semi-batch ALD apparatus, the mixing of reaction gases is suppressed by flowing a purge gas between the reaction gas supply means like a curtain (see, for example, Patent document 4).

Another method was invented in which a substrate is held in the air by a stream of gas blown from above and below, while the substrate is transported horizontally to deposit a film. In this method, a precursor, a purge gas and an oxidant gas are blown from above toward the substrate in each zone, and a purge gas is blown from below toward the substrate. ALD processing with excellent processing speed is performed by moving the substrate horizontally in the apparatus consisting of multiple zones (see, for example, Patent document 5).

As an epitaxial growth apparatus, a method was developed in which substrates standing vertically are arranged in a doughnut-shaped area as a whole. In this method, a circular cluster of wafer carriers creates tapered cavities, with each cavity holding two wafers facing each other. A process gas enters at the outer diameter defined by the cavity and flows toward the center of the cavity. This means that the closer the gas flow is to the center of the cavity, the faster the gas velocity becomes, which reduces the depletion of process gas at the downstream portion, resulting in a smaller difference in deposition rate between the outer and inner parts of the cavity (see, for example, FIG. 8 of Patent document 6 and pp. 56-57 of Non-patent document 1).

As a film deposition apparatus, a method of arranging multiple substrate mounting surfaces inclined with respect to the vertical plane has been disclosed (see, for example, Patent document 7-9). Also disclosed is an ALD apparatus that holds substrates vertically (see, for example, Patent document 10).

### PRIOR ART DOCUMENT

### Patent Document

[Patent document 1] Japanese Patent Publication No. 2004-6801.
[Patent document 2] Japanese Patent Publication No. 2014-201804.
[Patent document 3] U.S. Pat. No. 5,225,366.
[Patent document 4] U.S. Pat. No. 6,576,062.
[Patent document 5] U.S. Pat. No. 10,837,107.
[Patent document 6] Japanese Patent Publication No. 1989-144617.
[Patent document 7] Japanese Patent Publication No. 1987-023983.
[Patent document 8] Japanese Patent Publication No. 1996-139031.
[Patent document 9] Japanese Patent Publication No. 1973-054868.
[Patent document 10] Japanese Patent Publication No. 2004-292852.

### Non-Patent Document

[Non-patent document 1] Handbook of Thin Film Deposition Techniques Principles, Methods, Equipment and Applications, Second Edition (Materials and Processing Technology), edited by Krishna Seshan, CRC Press (2001).

### SUMMARY OF INVENTION

### Problems to be Solved by Invention

However, the batch ALD technology described in Patent document 1, shown as prior art, has a large number of substrates that can be processed at one time but requires the entire vacuum vessel to be filled with process gases, thus taking time to switch between different gases and resulting in a low processing speed. In addition, since a thin film is formed on the back surface of the substrate as well as the front side, many applications require an additional backside etching process.

With the ALD technologies described in Patent documents 2-4, shown as prior art, the number of substrates that can be processed at one time is small, resulting in a small processing speed.

The ALD technology described in Patent document 5 can be applied to extremely thin substrates (approximately 200 μm or less) such as solar cells, but for thick substrates (approximately 700 μm or more) such as wafers for semiconductor integrated circuits, the substrate is too heavy and cannot be stably transferred, making it difficult to apply. Moreover, the total length of the equipment needs to be extremely long to increase the processing speed, resulting in low area productivity (number of substrates that can be processed per unit time and unit area).

The epitaxial growth technology described in Patent document 6 and Non-patent document 1 was invented to maximize the number of substrates that can be processed at one time in a limited space, but while the difference in deposition rate between the outer and inner parts of the cavity is small, it does not use a shower head, which results in uneven deposition rates in the vertical direction. In particular, the deposition rate tends to be higher in the upper part of the substrate because gases are supplied mainly from above. Although FIG. 8 of Patent document 6 discloses a configuration in which different types of gases A and B are supplied, the spaces between two facing substrates are connected to each other through wide openings. Therefore, when performing ALD deposition, it is necessary to fill the entire vacuum vessel with either gas A or gas B to avoid mixing gases A and B, requiring time to switch between different gases and thus resulting in a slow processing speed.

Also with the deposition apparatuses described in Patent documents 7-10, the spaces between two facing substrates are connected to each other through wide openings, and there are no independent gas flow paths for each of the two substrates, requiring time to switch between different gases and resulting in low processing speeds for ALD deposition.

The present invention was made in view of these problems to provide a film deposition apparatus and method with excellent uniformity, high processing speed and high area productivity when performing deposition by ALD, epitaxial growth or CVD.

### Means to Solve Problems

A first invention of the present application is a film deposition apparatus comprising: a reactor; a plurality of substrate mounting surfaces inclined with respect to a vertical plane; a susceptor comprising the substrate mounting surface, wherein two of the plurality of substrate mounting surfaces face each other such that a distance between the two of the plurality of substrate mounting surfaces becomes wider the higher they are; and a gas nozzle that injects a gas downward between the two substrate mounting surfaces, wherein the gas nozzle has an aperture with a larger penetrating area toward a center of the substrate mounting surfaces than toward a periphery of the substrate mounting surfaces.

A second invention of the present application is a film deposition apparatus comprising: a reactor; a plurality of substrate mounting surfaces inclined with respect to a vertical plane; a susceptor comprising the substrate mounting surface, wherein two of the plurality of substrate mounting surfaces face each other such that a distance between the two of the plurality of substrate mounting surfaces becomes wider the higher they are; a gas nozzle that injects a gas downward between the two substrate mounting surfaces; and a moving mechanism moving the susceptor horizontally in the reactor, wherein the gas nozzle is divided into a plurality of gas nozzle groups in a direction of movement of the moving mechanism, each of the gas nozzle groups is capable of injecting a different type of gas, a plurality of susceptors is provided and arranged side by side, the moving mechanism moves the susceptors in a direction in which the plurality of susceptors is arranged, the plurality of susceptors is arranged in a rectangular space in the reactor, and the moving mechanism is a sliding mechanism moving the plurality of susceptors in a linear direction in the rectangular space.

A third invention of the present application is a film deposition apparatus comprising: a reactor; a plurality of substrate mounting surfaces inclined with respect to a vertical plane; a susceptor comprising the substrate mounting surface, wherein two of the plurality of substrate mounting surfaces face each other such that a distance between the two of the plurality of substrate mounting surfaces becomes wider the higher they are; and a moving mechanism moving the susceptor horizontally in the reactor, wherein a gas nozzle divided into a plurality of gas nozzle groups in a direction of movement of the moving mechanism injects a different type of gas from each of the gas nozzle groups, each of the gas nozzle groups is capable of injecting either a precursor-containing gas, a purge gas or a reactant-containing gas, and a gas nozzle group injecting the purge gas is arranged between a gas nozzle group injecting the precursor-containing gas and a gas nozzle group injecting the reactant-containing gas.

A fourth invention of the present application is a film deposition method comprising the steps of: moving and mounting a substrate from outside a reactor on a plurality of substrate mounting surfaces provided in the reactor that is inclined with respect to a vertical plane; exhausting gas from the reactor while supplying a gas into the reactor; and moving the substrate from the substrate mounting surface to an outside of the reactor to remove the substrate from the reactor, wherein two of the plurality of substrate mounting surfaces face each other such that a distance between the two of the plurality of substrate mounting surfaces becomes wider the higher they are, the substrate mounting surface is moved horizontally in the reactor by a moving mechanism moving the substrate mounting surface horizontally in the reactor, a gas nozzle divided into a plurality of gas nozzle groups in a direction of movement of the moving mechanism injects a different type of gas from each of the gas nozzle groups, the plurality of substrate mounting surfaces is arranged in a rectangular space in the reactor, and the plurality of substrate mounting surfaces is moved in a linear direction in the rectangular space.

A fifth invention of the present application is a film deposition method comprising the steps of: moving and mounting a substrate from outside a reactor on a plurality of substrate mounting surfaces provided in the reactor that is inclined with respect to a vertical plane; exhausting gas from the reactor while supplying a gas into the reactor; and moving the substrate from the substrate mounting surface to an outside of the reactor to remove the substrate from the reactor, wherein two of the plurality of substrate mounting surfaces face each other such that a distance between the two of the plurality of substrate mounting surfaces becomes wider the higher they are, the substrate mounting surface is moved horizontally in the reactor by a moving mechanism moving the substrate mounting surface horizontally in the reactor, a gas nozzle divided into a plurality of gas nozzle groups in a direction of movement of the moving mechanism injects a different type of gas from each of the gas nozzle groups, each of the gas nozzle groups is capable of injecting either a precursor-containing gas, a purge gas or a reactant-containing gas, and a gas nozzle group injecting the purge gas is arranged between a gas nozzle group injecting the precursor-containing gas and a gas nozzle group injecting the reactant-containing gas.

A sixth invention of the present application is a film deposition apparatus comprising: a reactor; a plurality of susceptors comprising a substrate mounting surface inclined with respect to a vertical plane in the reactor, wherein the plurality of susceptors is arranged horizontally, and two of the plurality of susceptors face each other such that a distance between the two of the plurality of substrate mounting surfaces becomes wider the higher they are; and a moving mechanism moving the susceptor horizontally in the reactor, wherein a gas nozzle divided into a plurality of gas nozzle groups in a direction of movement of the moving mechanism injects a different type of gas from each of the gas nozzle groups, each of the gas nozzle groups is capable of injecting either a precursor-containing gas, a purge gas or a reactant-containing gas, and a gas nozzle group injecting the purge gas is arranged between a gas nozzle group injecting the precursor-containing gas and a gas nozzle group injecting the reactant-containing gas.

For the film deposition apparatus of the first, third or sixth invention of the present application, the plurality of susceptors is preferably arranged radially in a doughnut-shaped space in the reactor, and a rotating mechanism rotating the plurality of susceptors in a circumferential direction in the doughnut-shaped space is preferably provided.

More preferably, the plurality of susceptors is arranged on a susceptor holder, a diameter of the susceptor holder is larger than a diameter of an inner wall of the reactor, and an outermost part of the susceptor holder is engaged in a groove formed all the way around the inner wall of the reactor.

Further, the plurality of susceptors is preferably arranged on a susceptor holder, and a top plate integrated with the susceptor holder above the plurality of susceptors is preferably provided, wherein the top plate rotates together with the susceptors and the susceptor holder.

More preferably, a diameter of the top plate is larger than a diameter of the inner wall of the reactor, an outermost part of the top plate is engaged in a groove formed all the way around the inner wall of the reactor, and a purge gas or an inert gas is supplied between the top plate and a ceiling surface of the reactor.

Preferably, a rotating exhaust port rotating together with the susceptors and exhausting a space between the two susceptors is provided.

A seventh invention of the present application is a film deposition method comprising the steps of: moving and mounting a substrate from outside a reactor on a substrate mounting surface provided on a plurality of susceptors comprising the substrate mounting surface inclined with respect to a vertical plane in the reactor; exhausting gas from the reactor while supplying a gas into the reactor; and moving the substrate from the substrate mounting surface to an outside of the reactor to remove the substrate from the reactor, wherein the plurality of susceptors is arranged horizontally, two of the plurality of susceptors face each other such that a distance between the two of the plurality of substrate mounting surfaces becomes wider the higher they are, the substrate mounting surface is moved horizontally in the reactor by a moving mechanism moving the substrate mounting surface horizontally in the reactor, a gas nozzle divided into a plurality of gas nozzle groups in a direction of movement of the moving mechanism injects a different type of gas from each of the gas nozzle groups, each of the gas nozzle groups is capable of injecting either a precursor-containing gas, a purge gas or a reactant-containing gas, and a gas nozzle group injecting the purge gas is arranged between a gas nozzle group injecting the precursor-containing gas and a gas nozzle group injecting the reactant-containing gas.

For the film deposition method of the fourth, fifth or seventh invention of the present application, the plurality of substrate mounting surfaces is preferably arranged radially in a doughnut-shaped space in the reactor, and the plurality of substrate mounting surfaces is preferably rotated in a circumferential direction in the doughnut-shaped space.

These configurations provide a film deposition apparatus and method with excellent uniformity, high processing speed and high area productivity.

### Effects of Invention

The present invention provides a film deposition apparatus and method with excellent uniformity, high processing speed and high area productivity when performing deposition by ALD, epitaxial growth or CVD.

### BRIEF DESCRIPTION OF DRAWINGS

FIG. 1 is a plan view of a configuration of a film deposition apparatus in a first embodiment of the present invention.

FIG. 2 is a perspective view of a configuration of a susceptor in the first embodiment of the present invention.

FIG. 3 is a perspective view of the configuration of the susceptor in the first embodiment of the present invention.

FIG. 4 is a perspective view of the configuration of the film deposition apparatus in the first embodiment of the present invention.

FIG. 5 is a plan view of an arrangement of susceptors in the first embodiment of the present invention.

FIG. 6 is a cross-sectional view of the configuration of the film deposition apparatus in the first embodiment of the present invention.

FIG. 7 is a cross-sectional development view of the configuration of the film deposition apparatus in the first embodiment of the present invention.

FIG. 8 is a cross-sectional view of the configuration of the film deposition apparatus in the first embodiment of the present invention.

FIG. 9 is a cross-sectional view of a configuration of a film deposition apparatus in a second embodiment of the present invention.

FIG. 10 is a cross-sectional view of a configuration of a film deposition apparatus in a third embodiment of the present invention.

FIG. 11 is a cross-sectional view of a configuration of a film deposition apparatus in a fourth embodiment of the present invention.

FIG. 12 is a cross-sectional view of the configuration of the film deposition apparatus in the fourth embodiment of the present invention.

FIG. 13 is a plan view of a configuration of a film deposition apparatus in a fifth embodiment of the present invention.

FIG. 14 is a perspective view of a configuration of a susceptor in the fifth embodiment of the present invention.

FIG. 15 is a perspective view of the configuration of the film deposition apparatus in the fifth embodiment of the present invention.

FIG. 16 is a cross-sectional view of the configuration of the film deposition apparatus in the fifth embodiment of the present invention.

FIG. 17 is a cross-sectional view of the configuration of the film deposition apparatus in the fifth embodiment of the present invention.

FIG. 18 is a perspective view of a configuration of a gas nozzle in a sixth embodiment of the present invention.

FIG. 19 is a plan view of a configuration of a film deposition apparatus in a seventh embodiment of the present invention.

FIG. 20 is a cross-sectional view of the configuration of the film deposition apparatus in the seventh embodiment of the present invention.

FIG. 21 is a perspective view of a configuration of a gas nozzle in the seventh embodiment of the present invention.

FIG. 22 is a cross-sectional view of a configuration of a film deposition apparatus in an eighth embodiment of the present invention.

FIG. 23 is a plan view of a configuration of a film deposition apparatus in a ninth embodiment of the present invention.

FIG. 24 is a cross-sectional view of the configuration of the film deposition apparatus in the ninth embodiment of the present invention.

FIG. 25 is a cross-sectional view of a configuration of a film deposition apparatus in a tenth embodiment of the present invention.

### DESCRIPTION OF EMBODIMENTS

The following is a description of the film deposition apparatus and method in the embodiments of the present invention, using drawings.

### First Embodiment

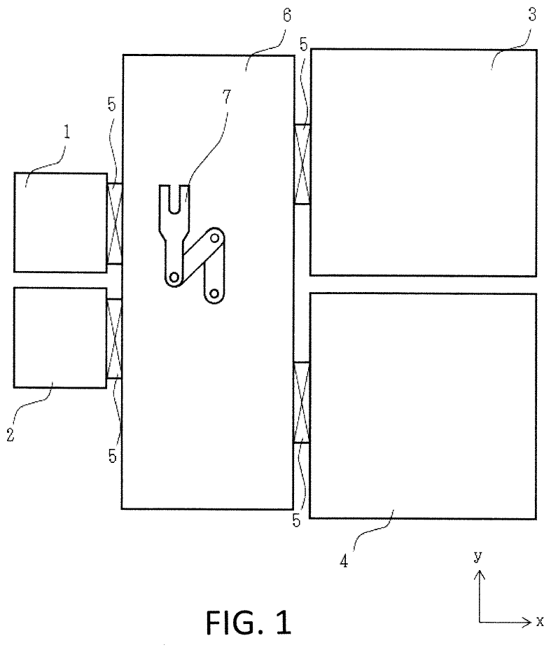

The following is a description of a first embodiment of the present invention, with reference to FIGS. 1-8.

FIG. 1 shows a configuration of a film deposition apparatus in the first embodiment and is a plan view of an entire apparatus, including a transport system.

The x-, y- and z-axis directions are included in each figure for easier understanding in the following explanations. In FIG. 1, the x-axis is oriented from left to right, the y-axis is from bottom to top, and the z-axis is from the back of the paper to the front.

FIG. 1 shows preliminary chambers 1 and 2 and reactors 3 and 4 connected to a robot chamber 6 via gates 5. The robot chamber 6 is equipped with a robot 7, which transfers substrates between the preliminary chamber 1 or 2 and the reactor 3 or 4. The preliminary chambers 1 and 2 can be load lock chambers with the reactors 3 and 4 and the robot chamber 6 operating in a vacuum at all times, or the preliminary chambers 1 and 2 and the robot chamber 6 can be atmospheric at all times with the reactors 3 and 4 being atmospheric for substrate loading/unloading and being in a vacuum for film deposition. Note that “vacuum” refers to a state of reduced pressure, meaning a pressure lower than atmospheric pressure. The robot chamber 6 may be further equipped with the ability to align a substrate.

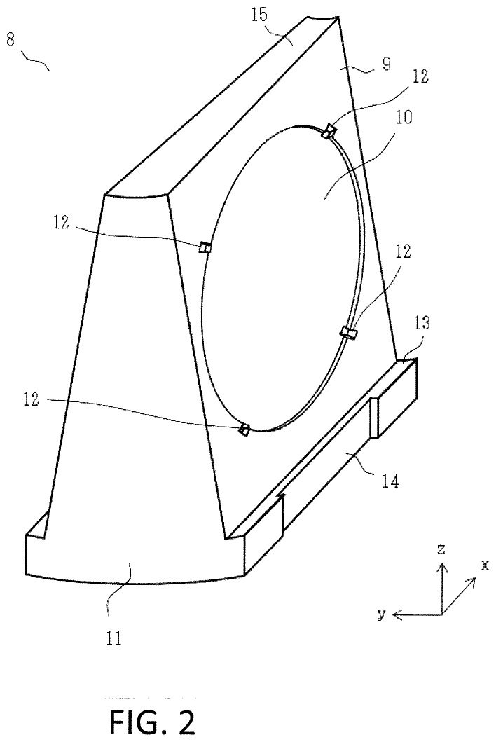

FIG. 2 is a perspective view of a configuration of a susceptor in the first embodiment of the present invention, showing the state in which the substrate is not mounted on a susceptor.

In FIG. 2, a susceptor 8 has a shape that approximates an isosceles triangle with a base parallel to a horizontal plane (it also approximates a trapezoid with the upper side shorter than the lower side) in a cross-section cut by a plane perpendicular to both a spot facing 10 as a substrate mounting surface provided on a slope 9 and the horizontal plane. In other words, the substrate mounting surface is tilted with respect to a vertical plane. The angle of the tilt is preferably 3-10 degrees with respect to the vertical plane, typically 5 degrees. If the angle of the tilt is too small, it is not preferable because the susceptor 8 needs to be made significantly larger to secure the distance between the top parts of the two susceptors 8 to allow a robotic arm to enter between the two susceptors 8, and conversely, if the angle of the tilt is too large, it is not preferable because the reactor 3 needs to be made significantly larger to provide the necessary number of the substrate mounting surfaces in the reactor 3. As described later, an inner wall of the reactor 3 is approximately cylindrical in shape, and an end face 11 in the x-axis direction forms part of a cylinder to arrange the susceptors 8 along a doughnut-shaped concave space inside the reactor 3. The end face on the side not visible in the figure also forms part of the cylinder. The spot facing 10 is provided on the slope 9 as the planes containing the two isosceles sides of this isosceles triangle. In other words, the spot facing 10 is also provided on the slope on the side that is not visible in the figure. Four recesses 12 are provided around the spot facing 10 to allow claws of the robotic arm of the robot 7 for transferring substrates to be released. The depth of the recesses 12 with respect to the slope 9 is slightly deeper than the spot facing 10 and is slightly inside a circle formed by the spot facing 10. Various types of robotic arms can be used as appropriate, and a Bernoulli chuck-type arm can be used to achieve smooth substrate mounting. The material for the susceptor 8 is preferably one that has high thermal conductivity with little deformation or deterioration, such as aluminum, stainless steel, silicon carbide, etc.

A susceptor bottom 13 is provided along the base of this isosceles triangle. A slit 14, which serves as a gas outlet, is provided near the center of the susceptor bottom 13. The slit 14, like the spot facing 10, is also provided on the side that is not visible in the figure. As described later, the inner wall of the reactor 3 is approximately cylindrical in shape, and a top surface 15 of the susceptor 8 is approximately fan-shaped to arrange the susceptors 8 along the doughnut-shaped concave space inside the reactor 3.

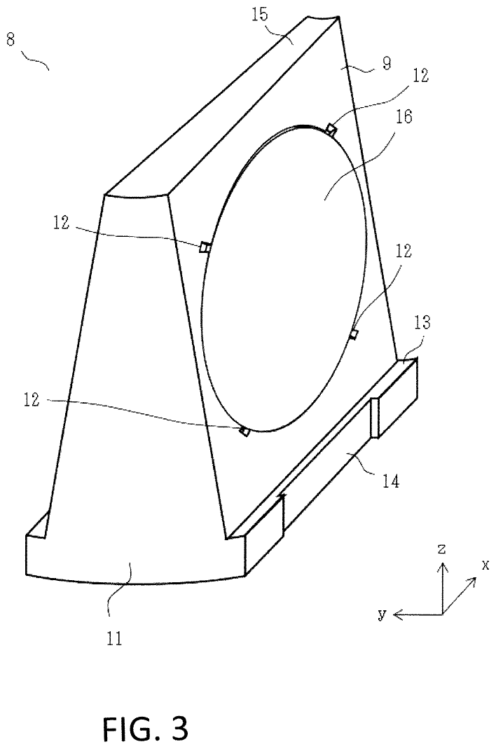

FIG. 3 is a perspective view of the configuration of the susceptor in the first embodiment of the present invention, showing the state in which the substrate is mounted on the susceptor.

FIG. 3 shows a substrate 16 mounted on the spot facing 10.

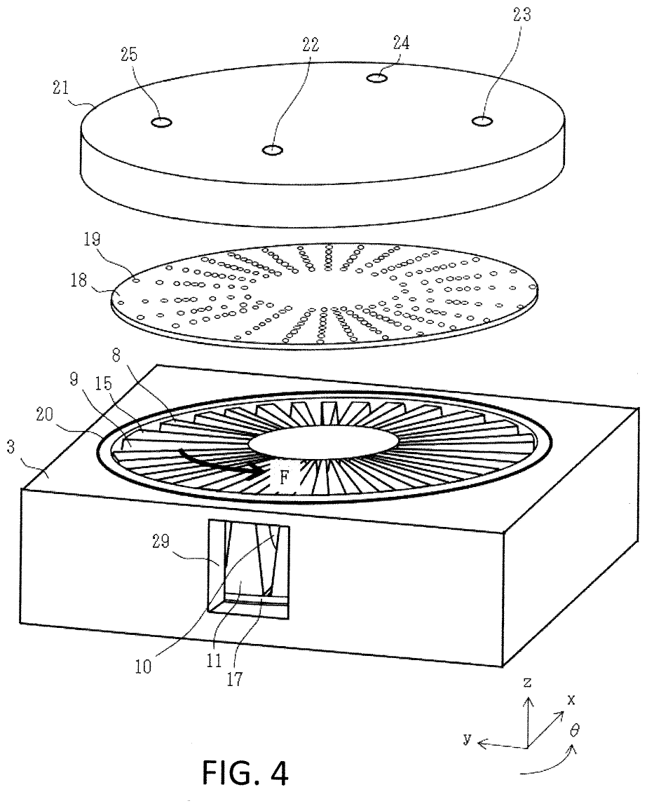

FIG. 4 is a perspective view of the configuration of the film deposition apparatus in the first embodiment of the present invention and is an exploded view of the configuration of the reactor. As described later, the susceptor 8 rotates in a circumferential direction of the doughnut-shaped space inside the reactor 3, with a direction of rotation indicated by 0 in FIG. 4.

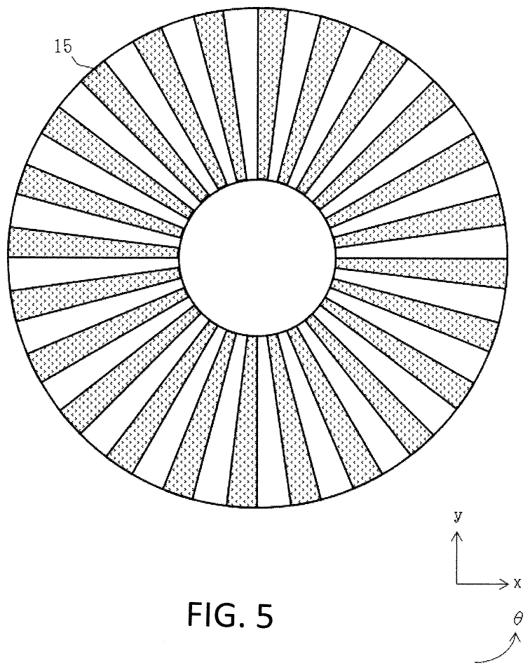

FIG. 5 is a plan view of an arrangement of susceptors in the first embodiment of the present invention, viewed from the top of the reactor 3. For simplicity, only the top surfaces 15 of the susceptors 8 are shown.

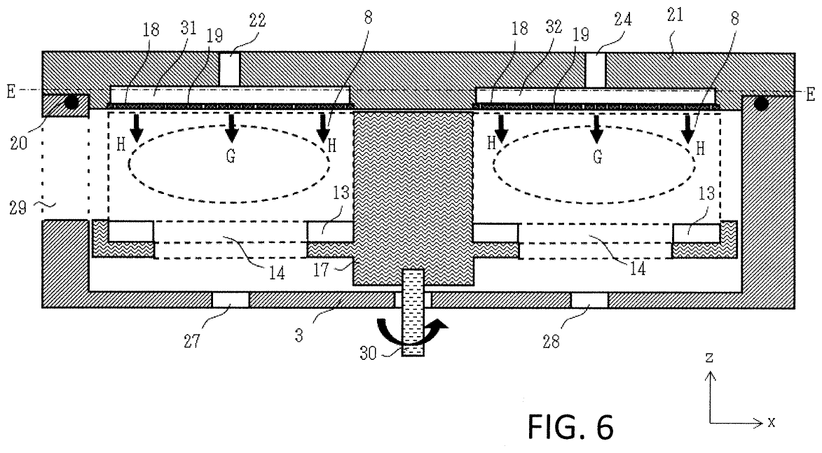

FIG. 6 shows the configuration of the film deposition apparatus in the first embodiment of the present invention and is a cross-sectional view of a configuration of the reactor when cut in a plane parallel to the xz-plane including the center of the reactor. The structures that would be visible at the back of the cross-section (gate opening, susceptor, spot facing, etc.) are shown schematically with dotted lines.

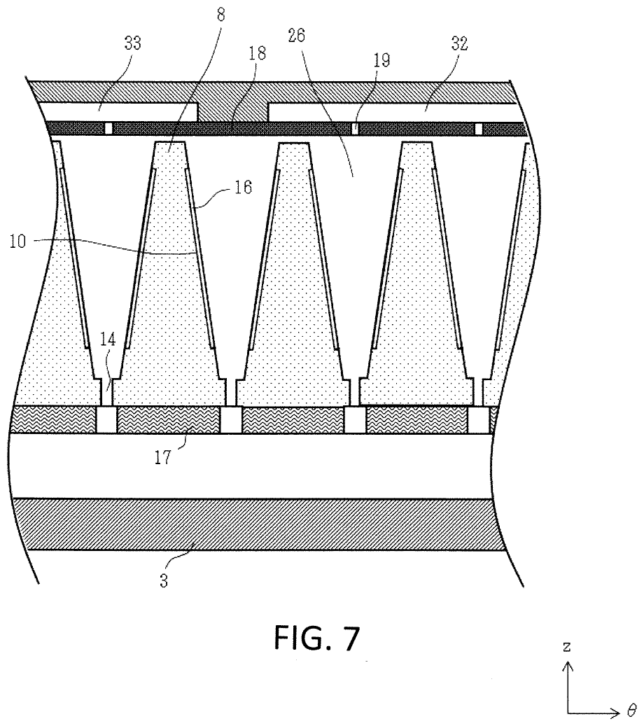

FIG. 7 shows the configuration of the film deposition apparatus in the first embodiment of the present invention and is part of a developed cross-sectional view of the configuration of the reactor when cut in a cylindrical plane perpendicular to the horizontal plane through the center of the multiple spot facings 10 on the multiple susceptors 8 arranged side by side, with the substrates 16 mounted on the spot facings 10.

In FIGS. 3-7, the reactor 3 is rectangular as a whole, but its inner wall is cylindrical in shape. The plurality of susceptors 8 is arranged side by side horizontally and radially on a susceptor holder 17 in the doughnut-shaped concave space inside the reactor 3. Gas outlet holes 19 provided on a shower plate 18 have a higher density in the portion toward the center than in the portion toward the periphery of the spot facings 10 and are through holes with a larger penetrating area in the portion toward the center than in the portion toward the periphery of the spot facings 10. A lid 21 is placed on top of the reactor 3 via an o-ring 20 to ensure airtightness. In other words, the film deposition process can be performed under vacuum conditions. Gas supply tubes are provided on the lid 21 in the circumferential direction in the following order: a purge gas supply tube 22, a precursor-containing gas supply tube 23, a purge gas supply tube 24 and an oxidant-containing gas supply tube 25. The gases supplied to the reactor 3 are exhausted from a V-shaped groove space 26 between the two susceptors 8, through the slit 14, and then merged at an exhaust manifold before being exhausted through exhaust ports 27 and 28.

The “portion toward the periphery of the spot facing 10” refers to the portion where the gas flow, when it travels straight from the gas outlet hole 19, does not pass near the center of the spot facing 10 but only near the periphery of the spot facing 10, as indicated by an arrow H in FIG. 6. The “portion toward the center of the spot facing 10” refers to the portion where the gas flow, when it travels straight from the gas outlet hole 19, passes near the center of the spot facing 10, as indicated by an arrow G in FIG. 6. Similarly, in the case where the spot facings 10 and the substrates 16 are different from a circle, such as rectangular, the “portion toward the periphery of the spot facing 10” refers to the portion where the gas flow, when it travels straight from the gas outlet hole 19, does not pass near the center of the spot facing 10 but only near the periphery of the spot facing 10, and the “portion toward the center of the spot facing 10” refers to the portion where the gas flow, when it travels straight from the gas outlet hole 19, passes near the center of the spot facing 10.

The phrase “having an aperture with a larger penetrating area” here means that the penetrating hole or group of penetrating holes occupies a larger area, i.e., the ratio of the penetrating area per unit area is larger. Needless to say, the ratio of the penetrating area can vary in various ways, by changing a parameter such as the density of the group of through holes, the size of the through holes and the width of the apertures. As an example, this embodiment employs a configuration in which the density of circular through holes of the same size results in the penetrating area that is larger in the portion toward the center than in the portion toward the periphery of the spot facing 10.

A gate opening 29 is provided on the side of the reactor 3, at the side of the susceptors 8 to exchange the substrates 16. The robotic arm of the robot 7 provided in the robot chamber 6 mounts the substrate 16 on the spot facing 10 through the gate opening 29, or removes the substrate 16 mounted on the spot facing 10 into the robot chamber 6. The susceptors 8 move horizontally inside the reactor 3 in the direction in which the plurality of susceptors 8 is arranged, i.e., they rotate by a rotating mechanism that rotates them in the circumferential direction in the doughnut-shaped space, so that the robotic arm can access all susceptors 8 through the gate opening 29. The “direction in which the plurality of susceptors 8 is arranged” here refers to the direction of arrangement that can be expressed by connecting the centers of the susceptors 8 arranged horizontally, which in this case is the direction of an arrow F (0 direction) in FIG. 4.

A rotating shaft 30 connected to the center of the susceptor holder 17 is provided at the bottom of the reactor 3, and the entire susceptor holder 17 rotates in the circumferential direction in the doughnut-shaped space together with all susceptors 8.

The shower plate 18 as a gas nozzle with a plurality of gas outlet holes 19 is provided on the lid 21, and gases are injected downward from purge gas supply manifolds 31 and 32 through the gas outlet holes 19 into the V-shaped groove space 26 between the two facing spot facings 10. It is configured so that the gas outlet holes 19 as gas introducing ports supply gases into the reactor 3 from above the spot facings 10.

As can be seen in FIG. 7, the plurality of susceptors 8 is arranged side by side horizontally and radially in the reactor 3, so that two of the plurality of spot facings 10 on the slope 9 face each other such that the distance between the spot facings 10 becomes wider the higher they are, and the V-shaped groove space 26 is formed between the two facing spot facings 10.

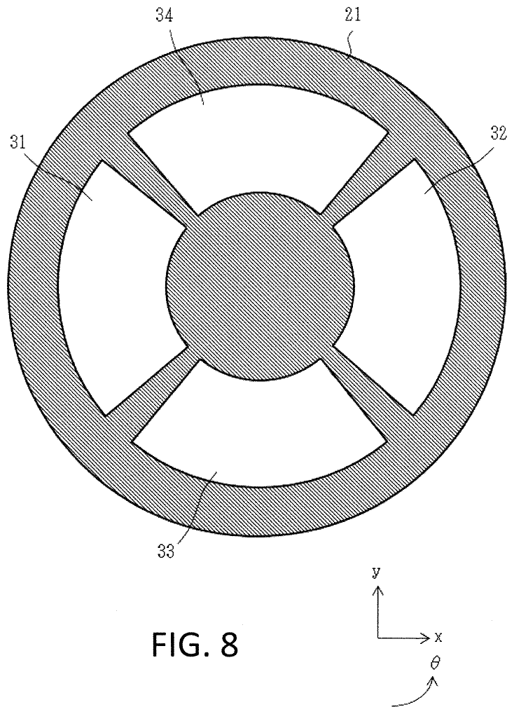

FIG. 8 shows the configuration of the film deposition apparatus in the first embodiment of the present invention and is an E-E cross-section of FIG. 6.

As shown in FIG. 8, four approximately fan-shaped supply manifolds, i.e., the purge gas supply manifolds 31 and 32, a precursor-containing gas supply manifold 33 and an oxidant-containing gas supply manifold 34, are provided, surrounded by four recesses in the lid 21 and the shower plate 18. This means that the shower plate 18 as a gas nozzle is divided into a plurality of gas nozzle groups in the circumferential direction in the doughnut shape, and each of the gas nozzle groups is capable of injecting a different gas. In other words, gas nozzle groups are provided, which are divided into a plurality of groups in a direction of movement (horizontal direction) of the moving mechanism. When necessary, only a purge gas can be supplied to the precursor-containing gas supply manifold 33 and the oxidant-containing gas supply manifold 34.

For simplicity, the operation will be described for the case where the preliminary chambers 1 and 2 are used as load lock chambers, and the reactors 3 and 4 and the robot chamber 6 are operated in a vacuum at all times. The temperature of the spot facings 10 as the substrate mounting surfaces is set to a predetermined temperature in advance. The appropriate temperature varies depending on the reactions, with 50-250° C., typically 80° C., for forming oxide films by ALD (atomic layer deposition) reactions on a resist film. The method of maintaining the temperature of the spot facing 10 at a constant temperature higher than room temperature can be selected from a variety of heating methods. For example, a resistance heater can be embedded in the susceptors 8, or lamp heating, induction heating or other methods can be used. With the gate 5 between the preliminary chamber 1 or 2 and the robot chamber 6 opened, the substrate 16 is taken out of the preliminary chamber 1 or 2 by the robot 7, and with the gate 5 between the robot chamber 6 and the reactor 3 opened, the substrate 16 is mounted on the spot facing 10 in the reactor 3 through the gate opening 29. In other words, the substrate 16 is moved and mounted from outside the reactor 3 on the spot facings 10 as the plurality of substrate mounting surfaces provided in the reactor 3 that is inclined with respect to the vertical plane. The rotation of the susceptor holder 17 is stopped during this step.

Next, the susceptor holder 17 is rotated, and then the substrate 16 is mounted on the next spot facing 10. By repeating these operations, the substrates 16 are mounted on all of the spot facings 10 in the reactor 3. Although the example here shows a case in which the susceptor holder 17 is rotated once per spot facing, the susceptor holder 17 may be rotated every time a certain number of substrates 16 are mounted on the multiple spot facings 10, depending on the configuration of the apparatus. The substrate exchange operation, in which the substrates 16 for which the deposition process has already been completed are removed from the spot facings 10 and the substrates 16 for which the deposition process has not been completed are mounted on the spot facings 10, may be continuously performed for each spot facing 10, or the substrates 16 for which the deposition process has not been completed may be sequentially mounted on the spot facings 10 after all substrates 16 in the reactor 3 have been removed from the spot facings 10. While the substrate 16 is being replaced or mounted, a small amount of purge gas or inert gas is supplied into the reactor 3 from the entire shower plate so that the pressure in the reactor 3 is higher than that in the robot chamber 6. This minimizes the concentration of unwanted gases that may enter the reactor 3 from the robot chamber 6 due to the opening of the gate 5.

After the substrates 16 have been mounted on all spot facings 10 in the reactor 3, the gate 5 is closed and a small amount of purge gas or inert gas is supplied from the entire shower plate into the reactor 3 for a few seconds. This reduces the concentration of unwanted gases that may enter the reactor 3 from the robot chamber 6 due to the opening of the gate 5.

Next, while operating the rotating mechanism and rotating the susceptor holder 17, four supply manifolds surrounded by the four recesses in the lid 21 and the shower plate 18, i.e., purge gas supply manifolds 31 and 32, a precursor-containing gas supply manifold 33 and an oxidant-containing gas supply manifold 34, supply a purge gas, a precursor-containing gas and an oxidant-containing gas into the reactor 3, respectively, and the reactor 3 is exhausted from the exhaust ports 27 and 28. Although two exhaust ports are shown here as an example, four exhaust ports may be provided in correspondence with four supply manifolds. Alternatively, each exhaust port may be exhausted by a separate pump, or a separate pressure regulator valve may be used for each exhaust port to finely control the pressure.

The flow rate of the purge gas in this case is approximately 10-1000 sccm (standard cubic centimeters per minute), typically 100 sccm.

Precursors can be selected as appropriate for the film material to be deposited. For example, TMA (trimethylaluminum) can be used for Al₂O₃ deposition, TEMAZ (tetrakis [ethylmethylamino] zirconium) for ZrO₂, methylcyclopentadienyl tris (dimethylamino) titanium for TiO₂ and 3DMAS (tris [dimethylamino] silane) for SiO₂. The precursor is supplied using a bubbler, a vaporizer, an ultrasonic vibrator or an injector, with the amount being controlled at 3-30 mg per time, typically 10 mg per time, depending on the rotation speed. Since it is difficult to supply a precursor alone to the reactor 3, it is usually diluted with an inert gas such as a noble gas. It is typically diluted with Ar gas, with a flow rate of the dilution gas of 10-1000 sccm, typically 100 sccm. Since the gas velocity in the V-shaped groove space 26 is larger the lower it is, the depletion of the precursor downstream is mitigated, and the difference in deposition rate between the upper and lower parts of the spot facing 10 becomes small. It is also preferable to heat the dilution gas to prevent the liquefaction of the precursor. The temperature of the dilution gas is approximately 40-150° C., typically 80° C. As the substrate 16 passes under the precursor-containing gas supply manifold, precursor molecules adsorb on the surface of the substrate 16. The reaction is self-regulating, with the adsorption reaction ending when no more sites are available for adsorption on the surface of the substrate 16. In other words, the surface of the substrate 16 is almost uniformly adsorbed with a thickness of one atomic layer of precursor molecules.

The ratio of precursor molecules adsorbed on the surface of the substrate 16 is higher in the portion toward the center than in the portion toward the periphery of the spot facing 10, but in the present invention, the gas outlet holes 19 provided on the shower plate 18 have a higher density in the portion toward the center than in the portion toward the periphery of the spot facing 10 and are through holes with a larger penetrating area in the portion toward the center than in the portion toward the periphery of the spot facing 10, leading to a more uniform and shorter adsorption step than conventional techniques, for example, using the film deposition apparatus described in Non-patent document 1.

The oxidant as a reactant can be selected as appropriate, and H₂O, H₂O₂, ozone, etc. can be used. For the deposition of a nitride film, a nitriding agent, for example, NH₃, can be used. If the oxidant is a liquid substance at room temperature, it is supplied using a bubbler, a vaporizer, an ultrasonic vibrator or an injector, as in the case of the precursor. For example, if H₂O is used, the amount is controlled at 1-100 mg per time, typically 10 mg per time, depending on the rotation speed. Since it is difficult to supply an oxidant alone to the reactor 3 in this case, it is usually diluted with an inert gas such as a noble gas. It is typically diluted with Ar gas, with a flow rate of the dilution gas of 10-1000 sccm, typically 100 sccm. If the oxidant is a liquid substance at room temperature, it is preferable to heat the dilution gas to prevent the liquefaction of the oxidant. The temperature of the dilution gas is approximately 40-150° C., typically 80° C. As the substrate 16 passes under the oxidant-containing gas supply manifold, a thin film with a thickness of approximately one atomic layer is deposited on the surface of the substrate 16 by the reaction between the precursor adsorbed on the surface of the substrate 16 and the oxidant. For example, when TMA is used as the precursor and H₂O as the oxidant, H₂O reacts with methyl groups of the precursor to yield methane as a byproduct, which is exhausted out of the reactor 3 through the gas exhaust ports 27 and 28, while hydroxylated Al₂O₃ remains on the surface to form a thin film.

The pressure in the reactor 3 is approximately 10-2000 mTorr, typically 100 mTorr. It is also possible, however, to perform ALD deposition at pressures close to atmospheric pressure, and the applicable pressure range is not limited to the above. The rotation speed is set so that each substrate 16 is exposed to each injection of gas for 0.1-10 s, typically 5 s, while the substrate 16 is deposited one time (while approximately one atomic layer of a thin film is formed), in this case, while the substrate 16 rotates once in the circumferential direction in the doughnut shape. For example, in this embodiment, four supply manifolds, i.e., the purge gas supply manifolds 31 and 32, the precursor-containing gas supply manifold 33 and the oxidant-containing gas supply manifold 34, are provided, surrounded by four recesses in the lid 21 and the shower plate 18. In other words, a gas nozzle group injecting the purge gas is arranged between a gas nozzle group injecting the precursor-containing gas and a gas nozzle group injecting the reactant-containing gas. Therefore, each substrate 16 is exposed to each of the gases in the order of the purge gas, the precursor-containing gas, the purge gas and the oxidant-containing gas only once while rotating in the circumferential direction in the doughnut shape. To set the time of exposure to each gas to 5 s, it can be set to rotate once in 5×4=20 s, i.e., at 3 rpm. To prevent each gas from mixing as much as possible above the surface on which the susceptors 8 are placed on the susceptor holder 17, the amount of gas supplied to each V-shaped groove space 26 can be equal, so that the difference in pressure between adjacent V-shaped groove spaces 26 is prevented. Alternatively, the amount of the purge gas can be slightly larger than that of the precursor-containing gas or the oxidant-containing gas. This effectively avoids mixing of the precursor and oxidant within each V-shaped groove space 26.

In this way, each substrate 16 is exposed to each of the gases in the order of the purge gas, the precursor-containing gas, the purge gas and the oxidant-containing gas by rotating the susceptor holder 17, forming an oxide thin film of approximately one atomic layer on the surface of the substrate 16. This process is realized by arranging gas nozzle groups in the circumferential direction in the doughnut shape, which inject gases in the order of the precursor-containing gas, the purge gas, the oxidant-containing gas and the purge gas. The susceptor holder 17 may rotate many times inside the reactor 3 to repeatedly perform this series of steps to obtain an oxide thin film of a predetermined thickness. The expression “approximately one atomic layer” is used here, and since a thin film formed in one cycle is approximately 1-2 angstroms when converted to a film thickness, for example, a thin film with a thickness of 20 nm needs a process of 100-200 cycles, requiring a total of 100-200 cycles of rotation of the susceptor holder 17 in the reactor 3.

The substrate 16 that has been deposited with a predetermined film thickness is taken out of the reactor 3 through the gate opening 29 from the spot facing 10 and stored in the preliminary chamber 1 or 2 using the robot 7, in the reverse steps of the substrate mounting. Two reactors 3 and 4 are provided in this embodiment, allowing deposition in one of the reactors while exchanging substrates in the other. In this way, the time-consuming processes of loading/unloading and film deposition can be simultaneously performed in multiple reactors, realizing a film deposition apparatus and method with even greater processing speed and even higher area productivity.

Unlike the film deposition apparatus described in the conventional techniques, for example, in Patent document 1, the back surface of the substrate 16 is protected by the susceptor 8, preventing the formation of a thin film on the back surface of the substrate 16. Therefore, there is no need for an additional process to etch the back surface. Further, since the volume of the area where the gases are to be supplied (the V-shaped groove space 26 between the two facing spot facings 10) is extremely smaller than that of conventional film deposition apparatuses, such as those described in Patent documents 1-4, being supplied with various gases directly from the gas outlet holes 19, the adsorption reaction, oxidation reaction and purging are all completed in a very short time, thus shortening the total film deposition time. The large number of substrates that can be processed at one time also increases the processing speed. In addition, since a large number of substrates can be processed in a small area, the area productivity is higher than that of conventional techniques, for example, the film deposition apparatus described in Patent document 5. Furthermore, since the substrate 16 is held by gravity in the spot facing 10 on the susceptor 8, even thick substrates (approximately 700 μm or more), such as wafers for semiconductor integrated circuits, can be stably processed.

The spaces between the two substrates facing each other (the V-shaped groove space 26 between the two facing spot facings 10) are connected to each other only through very narrow openings. This is because the distance between the top surface 15 of the susceptor 8 and the upper inner wall of the reactor 3 (the shower plate 18 in this embodiment) is extremely small. In other words, the risk of gas injected from a group of gas outlet holes 19 in a row into the V-shaped groove space 26 going over the top surface of the susceptor 8 and mixing into the adjacent V-shaped groove space 26 is extremely small. In addition, the slits 14 rotating together with the susceptors 8 as a rotating exhaust port to exhaust the space between the two susceptors 8 are provided, and the gas nozzle group injecting a purge gas is arranged between the gas nozzle group injecting a precursor-containing gas and the gas nozzle group injecting a reactant-containing gas. Therefore, even when the precursor-containing gas and reactant-containing gas are simultaneously supplied to the reactor 3, the risk of them mixing with each other is extremely small, and there is no need to switch between multiple gases, thus shortening the film deposition time compared to the film deposition apparatuses described in Patent documents 6-10. To obtain this effect, the distance between the top of the susceptors 8 (top surfaces 15) and the upper inner wall of the reactor 3 should be 1 mm or more and 10 mm or less. If the distance between the top surfaces 15 of the susceptors 8 and the upper inner wall of the reactor 3 is less than 1 mm, the top surfaces 15 of the susceptors 8 and the upper inner wall of the reactor 3 may come into contact when the rotation accuracy deteriorates due to the aging of the apparatus or other factors. Conversely, if the distance between the top surfaces 15 of the susceptors 8 and the upper inner wall of the reactor 3 is wider than 10 mm, the risk of the precursor-containing gas and the reactant-containing gas mixing with each other is slightly higher. In this embodiment, the upper inner wall of the reactor 3 is the bottom surface of the shower plate 18 but may be the bottom surface of the lid 21, depending on the configuration of the apparatus.

In this embodiment, approximately 20-30 susceptors 8 are provided and 40-60 substrates 16 can be mounted in the reactor 3, although the area productivity increases as the number of susceptors 8 provided in the reactor 3 increases. For example, the configuration may have 13 susceptors 8 to mount 26 substrates 16 in the reactor 3. Alternatively, the configuration may have 100 susceptors 8 to mount 200 substrates 16 in the reactor 3.

The case of continuously rotating the susceptor holder 17 after exchanging substrates is shown here as an example, although the gas flow is disrupted at the time when each gas outlet hole 19 is positioned right above the top surface 15 of each susceptor 8. Therefore, the process may be carried out intermittently, alternating between rotation and stop. This procedure has the advantage of ensuring a more reliable replacement of the precursor and oxidant with the purge gas. Alternatively, when the process is carried out intermittently, the precursor-containing gas supply manifold 33 and the oxidant-containing gas supply manifold 34 may also supply the purge gas, the gas flow rate supplied from each gas outlet hole 19 may be reduced, or the gas flow rate supplied from each gas outlet hole 19 may be stopped during rotation. This procedure has the advantage of effectively avoiding the mixing of the precursor and oxidant with the help of the purge gas, further ensuring a more reliable replacement. Alternatively, regardless of whether the rotation is continuously or intermittently alternating between rotation and stop, the precursor-containing gas supply manifold 33 and the oxidant-containing gas supply manifold 34 may also supply the purge gas, the gas flow rate supplied from each gas outlet hole 19 may be reduced, or the gas flow rate supplied from each gas outlet hole 19 may be stopped at the time when each gas outlet hole 19 is positioned right above the top surface 15 of each susceptor 8. This procedure has the advantage of effectively avoiding the mixing of the precursor and oxidant with the help of the purge gas, further ensuring a more reliable replacement.

The case in which the precursor-containing gas supply manifold 33, the purge gas supply manifolds 31 and 32 and the oxidant-containing gas supply manifold 34 are approximately the same size is shown here as an example, although the sizes may be varied depending on the process. For example, the purge gas supply manifolds 31 and 32 may be larger than the precursor-containing gas supply manifold 33 and the oxidant-containing gas supply manifold 34 to ensure a more reliable replacement of the precursor and oxidant with the purge gas.

### Second Embodiment

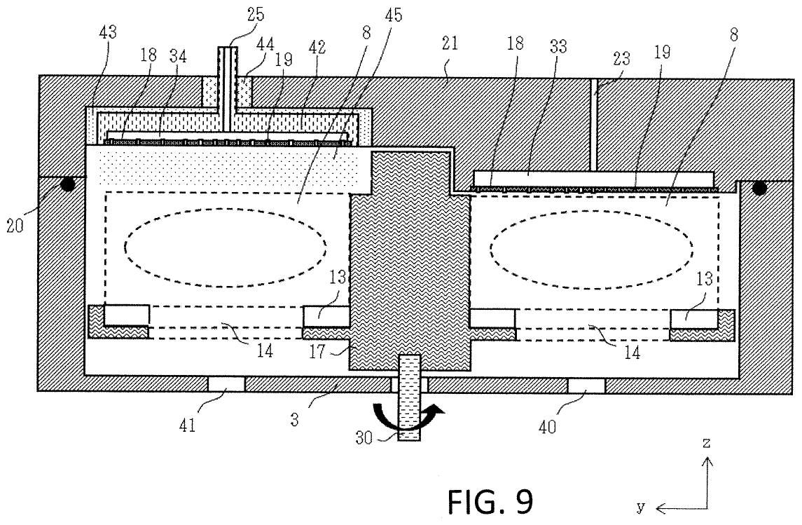

The following is a description of a second embodiment of the present invention, with reference to FIG. 9.

FIG. 9 shows a configuration of a film deposition apparatus in the second embodiment of the present invention and is a cross-sectional view of a configuration of the reactor when cut in a plane parallel to the yz-plane including the center of the reactor.

FIG. 9 shows a precursor-containing gas supply tube 23 and an oxidant-containing gas supply tube 25 on the lid 21. As in the case of the first embodiment, the lid 21 has four supply manifolds, and four exhaust ports in correspondence with these manifolds are provided. In FIG. 9, an exhaust port 40 is provided below the precursor-containing gas supply tube 23, and an exhaust port 41 below the oxidant-containing gas supply tube 25. The oxidant-containing gas supply tube 25 is connected to a fan-shaped electrode 42, which is electrically insulated from the lid 21 by insulation rings 43 and 44. The shower plate 18 is also separated from the other parts only in the fan-shaped portion that includes the gas outlet holes 19 for injecting a gas from the oxidant-containing gas supply tube 25. The electrode 42 is connected to a high-frequency power source, which is not shown, to generate a plasma 45 in the space between the shower plate 18 and the susceptors 8 by supplying high-frequency power to the electrode 42.

This configuration generates radicals, ions, ozone, etc., which have stronger oxidizing ability than gaseous oxidants by ionizing the oxidant-containing gas. This allows the process to be carried out at lower temperatures. This is also true for the nitridation process, in which the process can be carried out at lower temperatures by utilizing radicals and ions produced by generating a plasma from a gas containing NH₃. The lower temperature of the process allows for rapid adsorption of the precursor, further increasing the processing speed and area productivity. In addition, utilizing plasma has the advantage of forming a denser thin film.

### Third Embodiment

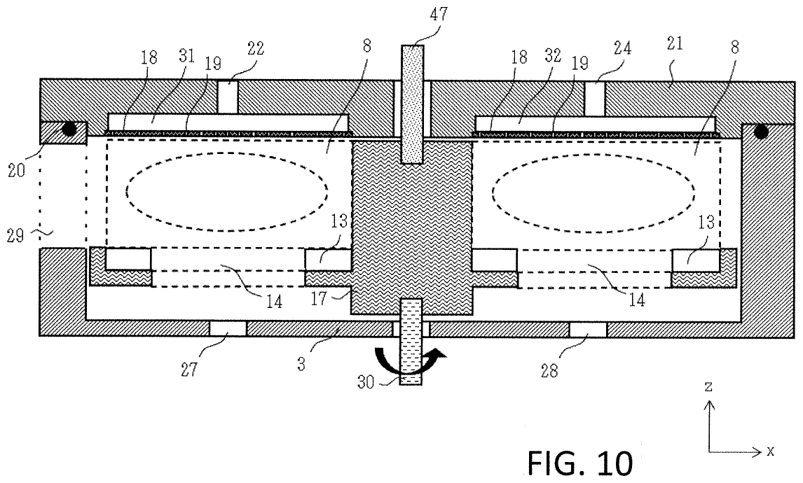

The following is a description of a third embodiment of the present invention, with reference to FIG. 10.

FIG. 10 shows a configuration of a film deposition apparatus in the third embodiment of the present invention and is a cross-sectional view of a configuration of the reactor when cut in a plane parallel to the xz-plane including the center of the reactor, corresponding to FIG. 6.

In the first embodiment, there is a risk of different types of gases mixing with each other through the gap between the uppermost part of the center of the susceptor holder 17 and the center of the lid 21, while in FIG. 10, the through hole in the center of the lid 21 is configured for an upper rotating shaft 47 to pass through. This configuration has the advantage of effectively preventing different types of gases from mixing with each other through the center of the reactor 3.

### Fourth Embodiment

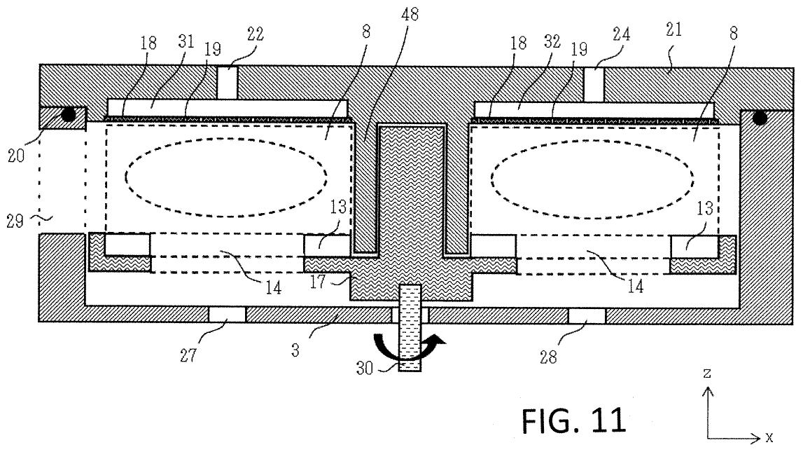

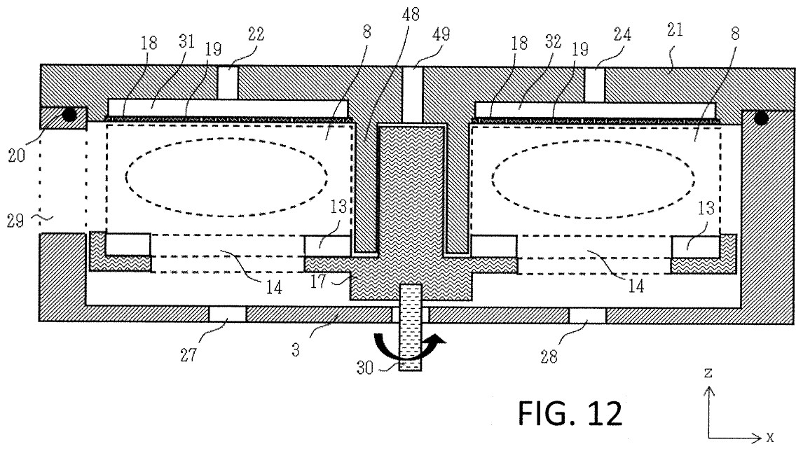

The following is a description of a fourth embodiment of the present invention, with reference to FIGS. 11 and 12.

FIGS. 11 and 12 show a configuration of a film deposition apparatus in the fourth embodiment of the present invention and is a cross-sectional view of a configuration of the reactor when cut in a plane parallel to the xz-plane including the center of the reactor, corresponding to FIG. 6.

In the first embodiment, there is a risk of different types of gases mixing with each other through the gap between the uppermost part of the center of the susceptor holder 17 and the center of the lid 21, while in FIG. 11, a hollow cylinder 48 is integrated into the lid 21 near its center. This configuration has the advantage of effectively preventing different types of gases from mixing with each other through the center of the reactor 3. Although the case in which the hollow cylinder 48 is integrated into the lid 21 near its center to lengthen the gas path around the center of the reactor 3 is shown here as an example, the same effect can be achieved with any other configuration as long as the susceptor holder 17 and lid 21 are fitted to each other.

To more effectively prevent different types of gases from mixing with each other through the center of the reactor 3, a central gas outlet hole 49 may be provided near the center of the lid 21, as shown in FIG. 12, to inject the purge gas or inert gas. Instead of having the susceptor holder 17 and the lid 21 fitting to each other, the central gas outlet hole 49 may be provided near the center of the reactor 3 in the configuration shown in FIG. 6 to inject the purge gas or inert gas.

### Fifth Embodiment

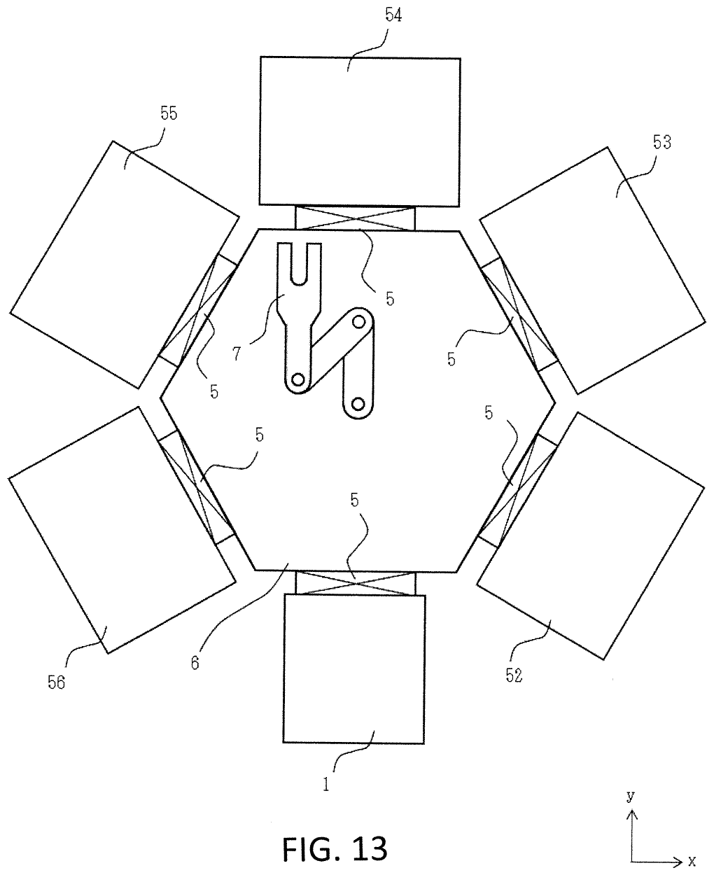

The following is a description of the fifth embodiment of the present invention, with reference to FIGS. 13-17.

FIG. 13 shows a configuration of a film deposition apparatus in the fifth embodiment of the present invention and is a plan view of the entire apparatus, including a transport system, corresponding to FIG. 1.

FIG. 13 shows a preliminary chamber 1 and reactors 52-56 connected to a robot chamber 6 via gates 5. The robot chamber 6 is equipped with a robot 7, which transfers substrates between the preliminary chamber 1 and one of the reactors 52-56. The preliminary chamber 1 can be a load lock chamber with the reactors 52-56 and the robot chamber 6 operating in a vacuum at all times, or the preliminary chamber 1 and the robot chamber 6 can be atmospheric at all times with the reactors 52-56 being atmospheric for substrate loading/unloading and being in a vacuum for film deposition. The robot chamber 6 may be further equipped with the ability to align a substrate.

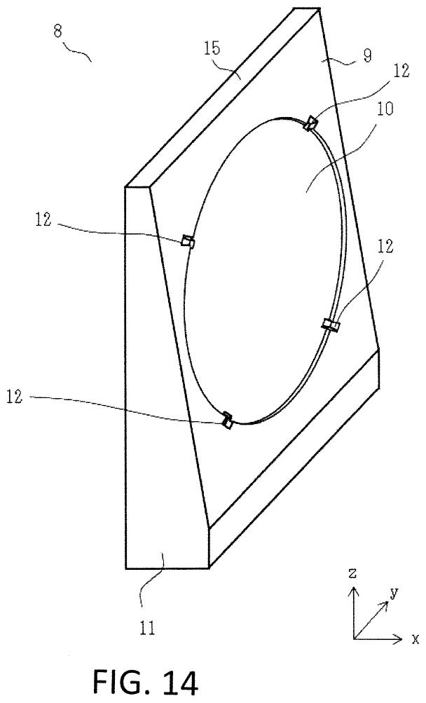

FIG. 14 is a perspective view of a configuration of a susceptor in the fifth embodiment of the present invention, showing the state in which the substrate is not mounted on the susceptor, corresponding to FIG. 2.

In FIG. 14, a susceptor 8 has a shape that approximates a right triangle with a base parallel to the horizontal plane (it also approximates a trapezoid with the upper side shorter than the lower side) in a cross-section cut by a plane perpendicular to both a spot facing 10 as a substrate mounting surface provided on a slope 9 and the horizontal plane. In other words, the substrate mounting surface is tilted with respect to a vertical plane. The angle of the tilt is preferably 3-10 degrees with respect to the vertical plane, typically 5 degrees. If the angle of the tilt is too small, it is not preferable because the susceptor 8 needs to be made significantly larger to secure the distance between the top parts of the two susceptors 8 to allow a robotic arm to enter between the two susceptors 8, and conversely, if the angle of the tilt is too large, it is not preferable because the reactors 52-56 needs to be made significantly larger to provide the necessary number of the substrate mounting surfaces in the reactors 52-56. As described later, the inner wall of the reactors 52-56 is approximately rectangular solid in shape, and an end face 11 in the y-axis direction is a plane to arrange the susceptors 8 along a rectangular-shaped concave space inside the reactors 52-56. The end face on the side not visible in the figure also is a plane. Unlike the first embodiment, the spot facing is not provided on the vertical surface on the side not visible in the figure. Four recesses 12 are provided around the spot facing 10 to allow claws of the robotic arm of the robot 7 for transferring substrates to be released. The depth of the recesses 12 with respect to the slope 9 is slightly deeper than the spot facing 10 and is slightly inside a circle formed by the spot facing 10. Various types of robotic arms can be used as appropriate, and a Bernoulli chuck-type arm can be used to achieve smooth substrate mounting. The material for the susceptor 8 is preferably one that has high thermal conductivity with little deformation or deterioration, such as aluminum, stainless steel, silicon carbide, etc.

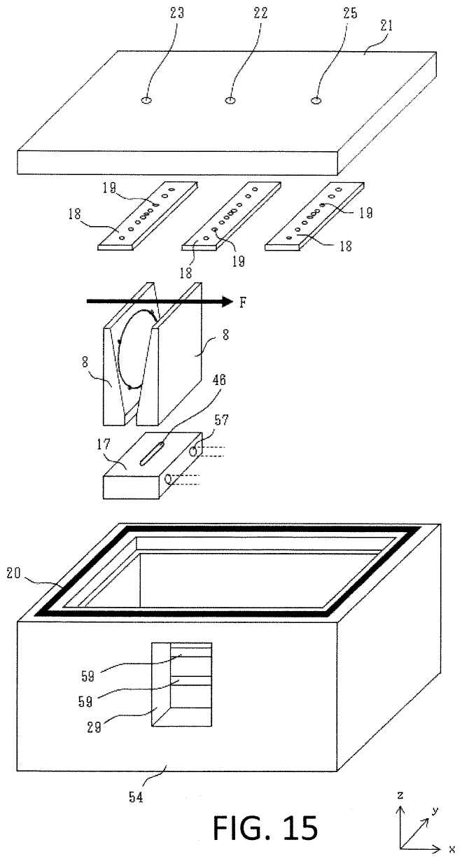

FIG. 15 is a perspective view of the configuration of the film deposition apparatus in the fifth embodiment of the present invention and is an exploded view of the configuration of the reactor. As an example, the configuration of the reactor 54 is described in detail below, while the other reactors 52, 53, 55 and 56 have similar configurations.

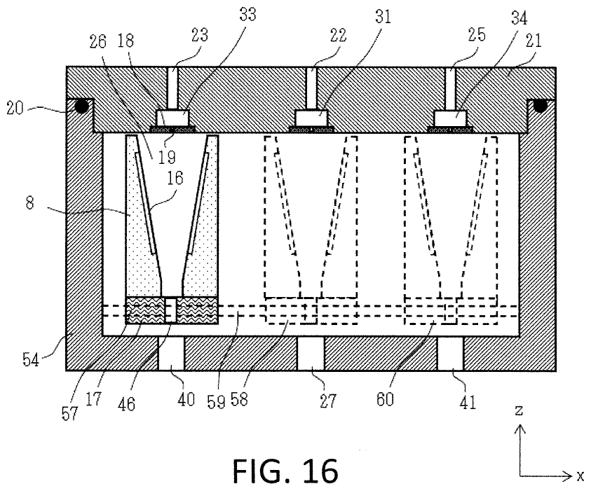

FIG. 16 shows the configuration of the film deposition apparatus in the fifth embodiment of the present invention and is a cross-sectional view of the configuration of the reactor when cut in a plane parallel to the xz-plane including the center of the reactor, with a susceptor holder 17, which is movable in the horizontal direction, being positioned in a precursor processing position.

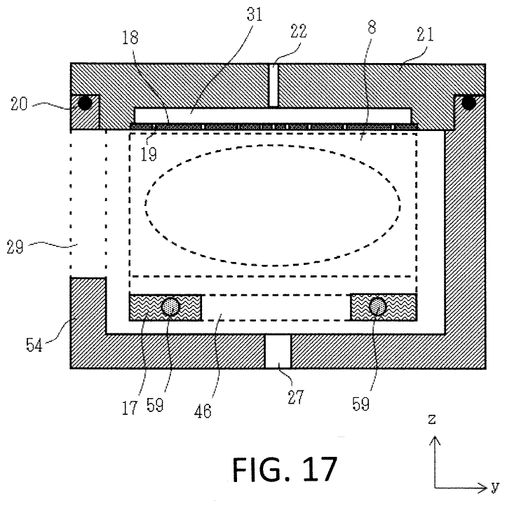

FIG. 17 shows the configuration of the film deposition apparatus in the fifth embodiment of the present invention and is a cross-sectional view of the configuration of the reactor when cut in a plane parallel to the yz-plane including the center of the reactor. The structures that would be visible at the back of the cross-section (gate opening, susceptor, spot facing, etc.) are shown schematically with dotted lines. It shows the susceptor holder 17, which is movable in the horizontal direction, being positioned in a purge position 58.

In FIGS. 15-17, the reactor 54 is rectangular as a whole, and its inner wall is rectangular in shape. Two susceptors 8 are arranged side by side horizontally and linearly on the susceptor holder 17 in the rectangular-shaped concave space inside the reactor 54. Gas outlet holes 19 provided on a shower plate 18 have a higher density in the portion toward the center than in the portion toward the periphery of the spot facings 10 and are through holes with a larger penetrating area in the portion toward the center than in the portion toward the periphery of the spot facings 10. A lid 21 is placed on top of the reactor 54 via an o-ring 20 to ensure airtightness. In other words, the film deposition process can be performed under vacuum conditions. Gas supply tubes are provided on the lid 21 in a linear direction in the following order: a precursor-containing gas supply tube 23, a purge gas supply tube 22 and an oxidant-containing gas supply tube 25. The gases supplied to the reactor 54 are exhausted from a V-shaped groove space 26 between the two susceptors 8, through a slit 46 provided on the susceptor holder 17, and then exhausted through exhaust ports 27, 40 and 41.

A gate opening 29 is provided on the side of the reactor 54, at the side of the susceptors 8 to exchange the substrates 16. The robotic arm of the robot 7 provided in the robot chamber 6 mounts the substrate 16 on the spot facing 10 through the gate opening 29, or removes the substrate 16 mounted on the spot facing 10 into the robot chamber 6. The susceptors 8 move horizontally inside the reactor 54 in the direction in which the plurality of susceptors 8 is arranged, i.e., they move by a sliding mechanism that moves them linearly in the rectangular-shaped space, so that the robotic arm can access all susceptors 8 through the gate opening 29. The “direction in which the plurality of susceptors 8 is arranged” here refers to the direction of arrangement that can be expressed by connecting the centers of the susceptors 8 arranged horizontally, which in this case is the direction of an arrow F (x direction) in FIG. 15.

The susceptor holder 17 has two through holes 57 that pass through the susceptor holder 17 in the x-axis direction, into which two shafts 59 provided in the lower part of the reactor 54 are inserted. The susceptor holder 17 is connected to a drive source and moves the susceptors 8 in the direction in which the plurality of susceptors 8 is arranged, using the shafts 59 as guides.

The shower plate 18 as a gas nozzle with a plurality of gas outlet holes 19 is provided on the lid 21, and gases are injected downward from a precursor-containing gas supply manifold 33 through the gas outlet holes 19 into the V-shaped groove space 26 between the two facing spot facings 10. It is configured so that the gas outlet holes 19 as gas introducing ports supply gases into the reactor 54 from above the spot facings 10.

When the susceptor holder 17 is positioned in the purge position 58, a purge gas supply manifold 31 injects the purge gas downward through the gas outlet holes 19 into the V-shaped groove space 26 between the two facing spot facings 10. Similarly, when the susceptor holder 17 is positioned in an oxidation position 60, an oxidant-containing gas supply manifold 34 injects the oxidant-containing gas downward through the gas outlet holes 19 into the V-shaped groove space 26 between the two facing spot facings 10. This means that the shower plate 18 as a gas nozzle is divided into a plurality of gas nozzle groups in the linear direction, and each of the gas nozzle groups is capable of injecting a different gas. In other words, gas nozzle groups are arranged in the direction of movement (horizontal direction) of the moving mechanism. When necessary, only a purge gas can be supplied to the precursor-containing gas supply manifold 33 and the oxidant-containing gas supply manifold 34.

As can be seen in FIG. 16, two susceptors 8 are arranged side by side horizontally and linearly in the reactor 54, so that two of the plurality of spot facings 10 on the slope 9 face each other such that the distance between the spot facings 10 becomes wider the higher they are, and the V-shaped groove space 26 is formed between the two facing spot facings 10.

For simplicity, the operation will be described for the case where the preliminary chamber 1 is used as a load lock chamber, and the reactors 52-56 and the robot chamber 6 are operated in a vacuum at all times. To avoid duplication of efforts, a description common to the first embodiment will be omitted.

The temperature of the spot facings 10 as the substrate mounting surfaces is set to a predetermined temperature in advance. Next, with the gate 5 between the preliminary chamber 1 and the robot chamber 6 opened, the substrate 16 is taken out of the preliminary chamber 1 by the robot 7, and with the gate 5 between the robot chamber 6 and the reactor 54 opened, the substrate 16 is mounted on the spot facing 10 in the reactor 54 through the gate opening 29. In other words, the substrate 16 is moved and mounted from outside the reactor 54 on the spot facings 10 as the plurality of substrate mounting surfaces provided in the reactor 54 that is inclined with respect to the vertical plane. The susceptor holder 17 is positioned in the purge position 58.

While the substrate 16 is being replaced or mounted, a small amount of purge gas or inert gas is supplied into the reactor 54 from the entire shower plate so that the pressure in the reactor 54 is higher than that in the robot chamber 6. This minimizes the concentration of unwanted gases that may enter the reactor 54 from the robot chamber 6 due to the opening of the gate 5.

After the substrates 16 have been mounted on two spot facings 10 in the reactor 54, the gate 5 is closed and a small amount of purge gas or inert gas is supplied from the entire shower plate into the reactor 54 for a few seconds. This reduces the concentration of unwanted gases that may enter the reactor 54 from the robot chamber 6 due to the opening of the gate 5.

Next, while operating the sliding mechanism and reciprocating the susceptor holder 17 in the x-axis direction, three supply manifolds surrounded by each of the three recesses in the lid 21 and the shower plate 18, i.e., the purge gas supply manifold 31, the precursor-containing gas supply manifold 33 and the oxidant-containing gas supply manifold 34, supply a purge gas, a precursor-containing gas and an oxidant-containing gas into the reactor 54, respectively, and the reactor 54 is exhausted from the exhaust ports 27, 40 and 41. Although the case shown here is a configuration with three exhaust ports, it may have only one exhaust port. Alternatively, each exhaust port may be exhausted by a separate pump, or a separate pressure regulator valve may be used for each exhaust port to finely control the pressure.

The type and flow rate of each gas and the pressure in the reactor 54 are the same as those in the first embodiment. In this way, the susceptor holder 17 is reciprocated in the x-axis direction between the precursor processing position and the oxidation position 60, while different gases are supplied to the reactor 54, to move the substrate mounting surfaces in the linear direction within the rectangular space.

When substrate 16 is positioned in the precursor processing position, the precursor molecules are adsorbed on the surface of the substrate 16. The reaction is self-regulating, with the adsorption reaction ending when no more sites are available for adsorption on the surface of the substrate 16. In other words, the surface of the substrate 16 is almost uniformly adsorbed with a thickness of one atomic layer of precursor molecules.

The ratio of precursor molecules adsorbed on the surface of the substrate 16 is higher in the portion toward the center than in the portion toward the periphery of the spot facing 10, but in the present invention, the gas outlet holes 19 provided on the shower plate 18 have a higher density in the portion toward the center than in the portion toward the periphery of the spot facing 10 and are through holes with a larger penetrating area in the portion toward the center than in the portion toward the periphery of the spot facing 10, leading to a more uniform and shorter adsorption step than conventional techniques, for example, using the film deposition apparatus described in Non-patent document 1.

When the substrate 16 is positioned in the oxidation position 60, a thin film with a thickness of approximately one atomic layer is deposited on the surface of the substrate 16 by the reaction between the precursor adsorbed on the surface of the substrate 16 and the oxidant. For example, when TMA is used as the precursor and H₂O as the oxidant, H₂O reacts with methyl groups of the precursor to yield methane as a byproduct, which is exhausted out of the reactor 54 through the gas exhaust ports 27, 40 and 41, while hydroxylated Al₂O₃ remains on the surface to form a thin film.

The movement speed is set so that each substrate 16 is exposed to each injection of gas for 0.1-10 s, typically 5 s, while the substrate 16 is deposited one time (while approximately one atomic layer of a thin film is formed), in this case, while the substrate 16 makes one reciprocal movement in the linear direction. For example, in this embodiment, three supply manifolds, i.e., the purge gas supply manifold 31, the precursor-containing gas supply manifold 33 and the oxidant-containing gas supply manifold 34, are provided, surrounded by three recesses in the lid 21 and the shower plate 18. In other words, a gas nozzle group injecting the purge gas is arranged between a gas nozzle group injecting the precursor-containing gas and a gas nozzle group injecting the reactant-containing gas. Therefore, each substrate 16 is exposed to each of the gases in the order of the purge gas, the precursor-containing gas, the purge gas and the oxidant-containing gas only once while making one reciprocal movement in the linear direction. To set the time of exposure to each gas to 5 s, it can be set to reciprocate once in 5×4=20 s, i.e., to move at a speed of three reciprocations per minute. To prevent each gas from mixing as much as possible above the surface on which the susceptors 8 are placed on the susceptor holder 17, the amount of gas supplied to each V-shaped groove space 26 can be equal, or the amount of the purge gas can be slightly larger than that of the precursor-containing gas or the oxidant-containing gas. This effectively avoids mixing of the precursor and oxidant within each V-shaped groove space 26.

In this way, each substrate 16 is exposed to each of the gases in the order of the purge gas, the precursor-containing gas, the purge gas and the oxidant-containing gas by reciprocating the susceptor holder 17 in the linear direction, forming an oxide thin film of approximately one atomic layer on the surface of the substrate 16. This process is realized by arranging, in the linear direction, the gas nozzle group injecting the purge gas between the gas nozzle group injecting the precursor-containing gas and the gas nozzle group injecting the reactant-containing gas. The susceptor holder 17 may reciprocate many times inside the reactor 54 to repeatedly perform this series of steps to obtain an oxide thin film of a predetermined thickness. The expression “approximately one atomic layer” is used here, and since a thin film formed in one cycle is approximately 1-2 angstroms when converted to a film thickness, for example, a thin film with a thickness of 20 nm needs a process of 100-200 cycles, requiring a total of 100-200 cycles of reciprocal movement of the susceptor holder 17 in the reactor 54.

The substrate 16 that has been deposited with a predetermined film thickness is taken out of the reactor 54 through the gate opening 29 from the spot facing 10 and stored in the preliminary chamber 1 using the robot 7, in the reverse steps of the substrate mounting. Five reactors 52-56 are provided in this embodiment, allowing deposition in four of the reactors while exchanging substrates in one reactor. In this way, the time-consuming processes of loading/unloading and film deposition can be simultaneously performed in multiple reactors, realizing a film deposition apparatus and method with even greater processing speed and even higher area productivity.

The film deposition apparatus in this embodiment is compact and small in scale, although its processing speed is smaller than that of the film deposition apparatus described in the first embodiment, and it is also useful as an apparatus for conducting preliminary experiments to design the details of the film deposition apparatus described in the first embodiment. To realize a film deposition apparatus and method with even higher processing speed and even higher area productivity, the number of the substrate mounting surfaces arranged in the reactor 54 can be increased to four, six, eight, etc. by, for example, arranging multiple susceptor holders 17 horizontally in the x-axis or y-axis direction.

The case of continuously reciprocating the susceptor holder 17 after exchanging substrates is shown here as an example, although the gas flow is disrupted at the time when each gas outlet hole 19 is positioned right above the top surface 15 of each susceptor 8. Therefore, the process may be carried out intermittently, alternating between movement and stop. This procedure has the advantage of ensuring a more reliable replacement of the precursor and oxidant with the purge gas. Alternatively, when the process is carried out intermittently, the precursor-containing gas supply manifold 33 and the oxidant-containing gas supply manifold 34 may also supply the purge gas, the gas flow rate supplied from each gas outlet hole 19 may be reduced, or the gas flow rate supplied from each gas outlet hole 19 may be stopped during movement. This procedure has the advantage of effectively avoiding the mixing of the precursor and oxidant with the help of the purge gas, further ensuring a more reliable replacement. Alternatively, regardless of whether the movement is continuously or intermittently alternating between movement and stop, the precursor-containing gas supply manifold 33 and the oxidant-containing gas supply manifold 34 may also supply the purge gas, the gas flow rate supplied from each gas outlet hole 19 may be reduced, or the gas flow rate supplied from each gas outlet hole 19 may be stopped at the time when each gas outlet hole 19 is positioned right above the top surface 15 of each susceptor 8. This procedure has the advantage of effectively avoiding the mixing of the precursor and oxidant with the help of the purge gas, further ensuring a more reliable replacement. Alternatively, the precursor-containing gas supply manifold 33 may supply the precursor-containing gas only when the susceptor holder 17 is positioned in the precursor processing position while the precursor-containing gas supply manifold 33 supplies the purge gas at any other time, and the oxidant-containing gas supply manifold 34 may supply the oxidant-containing gas only when the susceptor holder 17 is positioned in the oxidation position 60 while the oxidant-containing gas supply manifold 34 supplies the purge gas at any other time. This procedure has the advantage of effectively avoiding the mixing of the precursor and oxidant, further ensuring a more reliable replacement.

### Sixth Embodiment

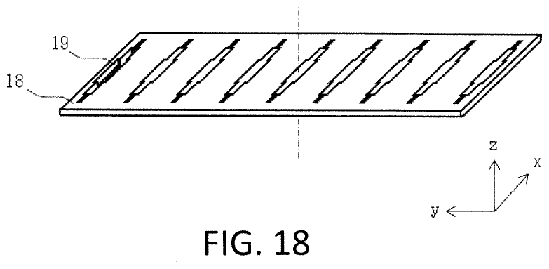

The following is a description of a sixth embodiment of the present invention, with reference to FIG. 18.

FIG. 18 is a perspective view of a configuration of a gas nozzle in the sixth embodiment of the present invention, corresponding to the shower plate 18 in FIG. 15. To make the shapes of the gas outlet holes 19 easier to understand, only the shape of each opening on the top side of the shower plate 18 is shown, except for the leftmost gas outlet hole 19.

In the first to fifth embodiments, the gas outlet holes 19 on the shower plate 18 are circular and have a higher density in the portion toward the center than in the portion toward the periphery of the spot facing 10, while in this embodiment, the gas outlet holes 19 are rectangular and their width in the y-axis direction is configured to be wider in the portion toward the center than in the portion toward the periphery of the spot facing 10, thereby making them through holes with a larger penetrating area in the portion toward the center than in the portion toward the periphery of the spot facing 10. Needless to say, there are many other possible modifications.

### Seventh Embodiment

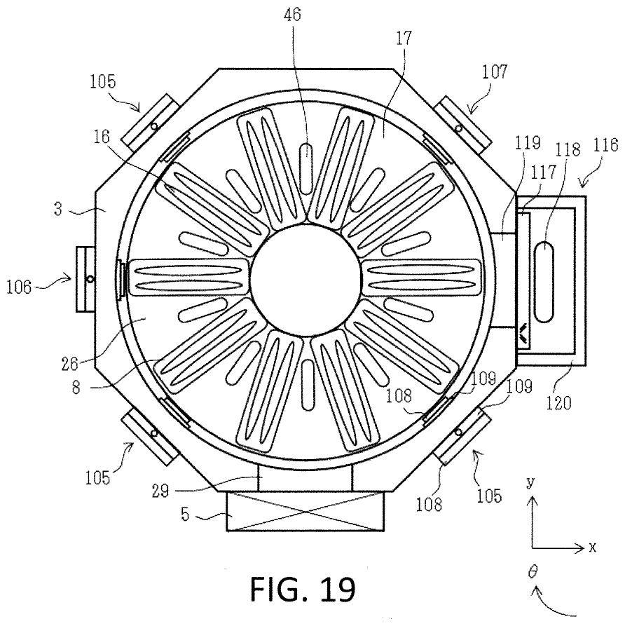

The following is a description of a seventh embodiment of the present invention, with reference to FIGS. 19-21.

FIG. 19 is a plan view of a configuration of a film deposition apparatus in the seventh embodiment of the present invention, viewed from the top below a top plate 104, which will be explained later.

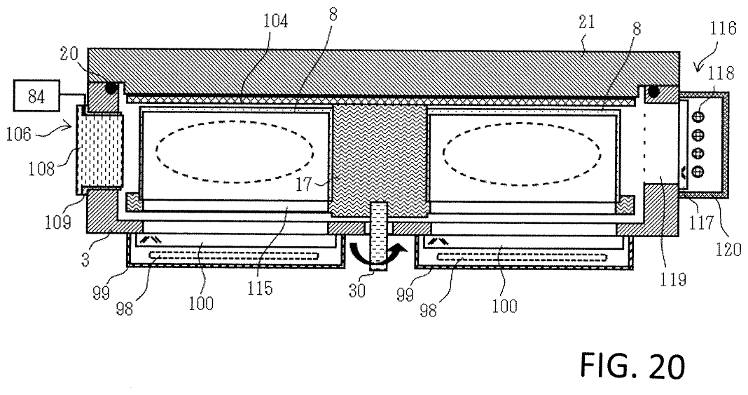

FIG. 20 shows the configuration of the film deposition apparatus in the seventh embodiment of the present invention and is a cross-sectional view of the configuration of the reactor when cut in a plane parallel to the xz-plane including the center of the reactor.

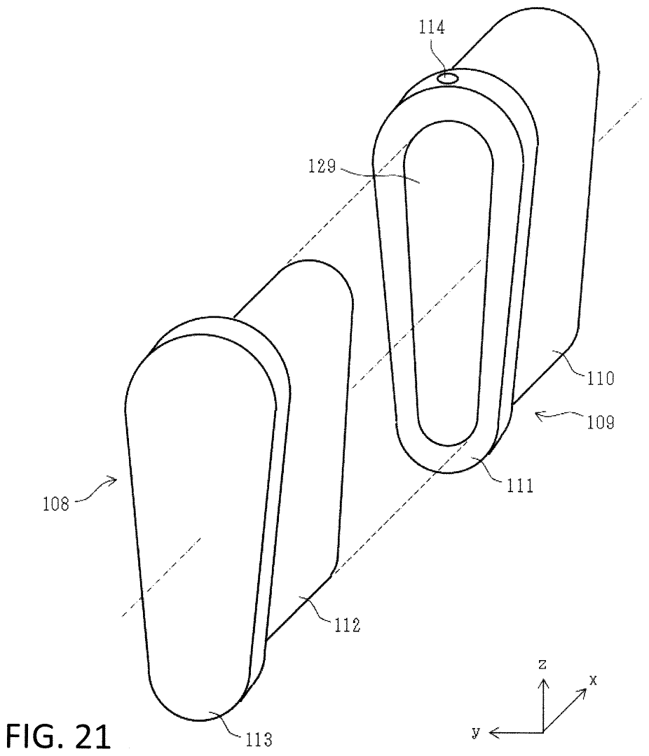

FIG. 21 is an exploded perspective view of a configuration of a gas nozzle in the seventh embodiment of the present invention.

The basic operation in this embodiment is the same as in the first embodiment. The susceptors 8 here are made of thin plates.

In FIGS. 19-21, the reactor 3 is an octagonal prism as a whole, but its inner wall is cylindrical in shape. The plurality of susceptors 8 is arranged side by side horizontally and radially on a susceptor holder 17 in a doughnut-shaped concave space inside the reactor 3. Each gas supply nozzle is arranged circumferentially on the side of the reactor 3 in the order of a purge gas supply nozzle 105, a precursor-containing gas supply nozzle 106, a purge gas supply nozzle 105, an oxidant-containing gas supply nozzle 107 and a purge gas supply nozzle 105 and injects each gas into a V-shaped groove space 26 between the two susceptors 8. A lid 21 is placed on top of the reactor 3 via an o-ring 20 to ensure airtightness. In other words, the film deposition process can be performed under vacuum conditions. The gases supplied to the reactor 3 are exhausted from the V-shaped groove space 26 between the two susceptors 8, through slits 46 (rotating exhaust ports that rotate together with the susceptors 8 and exhaust the space between the two susceptors 8), and then exhausted through exhaust ports that are not shown.

A gate opening 29 is provided on the side of the reactor 3, at the side of the susceptors 8 to exchange the substrates 16. A rotating shaft 30 connected to the center of the susceptor holder 17 is provided at the bottom of the reactor 3, and the entire susceptor holder 17 rotates in the circumferential direction in the doughnut-shaped space together with all susceptors 8.

Each gas supply nozzle has a similar configuration and consists of a cap 108 and a ring 109, injecting one type of gas. Specifically, the ring 109 has a belt-shaped portion 110, which forms an elongated ring in the z-direction (vertical direction) as a whole, and a brim portion 111, which is integrated with the belt-shaped portion 110 and has an inner wall surface similar in shape (identical in this embodiment) to the inner wall surface of the belt-shaped portion 110.

The cap 108 has a plate portion 112 with an outer wall surface similar in shape (identical in this embodiment) to the inner wall surface of the belt-shaped portion 110 of the ring 109, inserted into the belt-shaped portion 110 and a brim portion integrated with plate portion 113, which is integrated with the plate portion 112 and arranged overlapping the brim portion 111 of the ring 109. The plate portion 112 of the cap 108 is inserted into and penetrates an elongated hole 113 consisting of the interior of the belt-shaped portion 110 and the brim portion 111 of the ring 109, with its tip exposed in the reactor 3. Since the length in the x-direction of the plate portion 112 is slightly longer than the sum of the length in the x-direction of the belt-shaped portion 110 and the length in the x-direction of the brim portion 111, the tip of the plate portion 112 slightly protrudes in the direction toward the center than the tip of the belt-shaped portion 110 in the reactor 3.

The first gas supplied from a first gas supply unit 84, which consists of a mass flow controller, valve, etc., passes through an introduction hole 114 that penetrates from the outer wall of the brim portion 111 to the inner wall of the brim portion 111 and through a gap between the inner wall of the belt-shaped portion 110 and the outer wall of the plate portion 112, flowing from the opposite side of the brim portion 111. This means that the gas is injected toward the center of the reactor 3 into the V-shaped groove space 26 between the two facing spot facings 10.

In this embodiment, each of the parts comprising the cap 108 and the ring 109 is configured so that the higher it is, the wider it is in the y-direction. This corresponds to the fact that the higher it is, the wider the distance between the substrate mounting surfaces. Regarding the radial direction, the farther it is from the center of the reactor 3, the wider the distance between the substrate mounting surfaces. In other words, a gas flows from an area with a wider distance between the substrate mounting surfaces to an area with a narrower distance.

An inductively coupled plasma unit 116 as a plasma-generating device is provided opposite the precursor-containing gas supply nozzle 106. The inductively coupled plasma unit 116 consists of a quartz glass window 117 and a coil 118 and generates a plasma in an aperture 119 by supplying high-frequency power to the coil 118. The coil 118 is enclosed by a shield 120 to prevent the generation of electromagnetic noise. The oxidant-containing gas may also be supplied to the aperture 119.

Each susceptor 8 is made of thin plates, and its back side is heated by lamps 98 arranged below the susceptors 8. The lamps 98 are long, radially arranged straight tubes in the radial direction of the reactor 3, with reflectors 99 below the lamps 98. Light including infrared light emitted from the lamps 98, together with light reflected by the reflectors 99, is introduced into the reactor 3 through quartz glass windows 100 and irradiates the back surface of the susceptors 8 through openings 115 in the susceptor holder 17.

The top plate 104, which is integrated with the susceptor holder 17, is provided right below the lid 21 and above the susceptors 8. The top plate 104 rotates together with the susceptors 8 and the susceptor holder 17. Therefore, even when the distance between the top of the susceptors 8 and the bottom surface of the top plate 104 is extremely small, there is very little risk of the top of the susceptors 8 contacting the top plate 104 when the rotation accuracy deteriorates due to the aging or other factors. Alternatively, the top of the susceptors 8 can be designed to be in contact with the bottom surface of the top plate 104 at all times. This effectively prevents different types of gases from mixing with each other through the center of the reactor 3.

### Eighth Embodiment

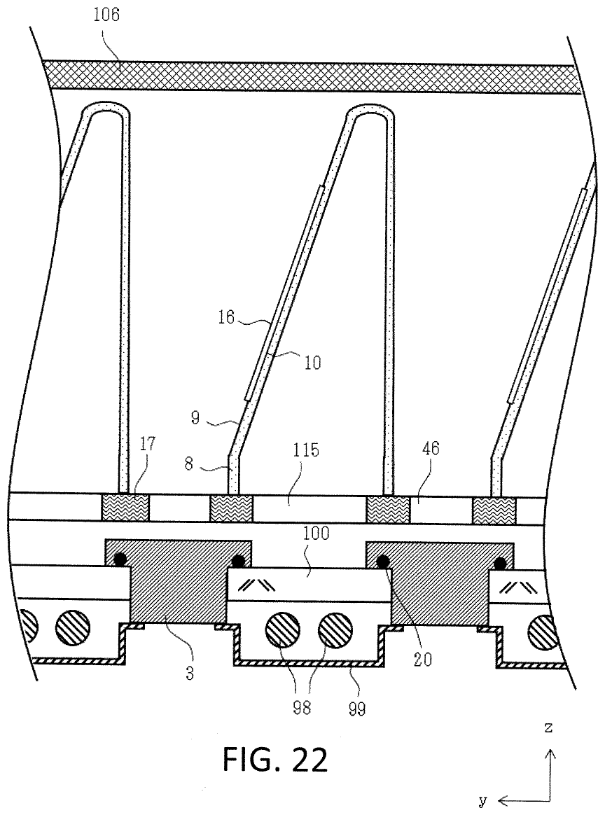

The following is a description of an eighth embodiment of the present invention, with reference to FIG. 22.

FIG. 22 shows a configuration of a film deposition apparatus in the eighth embodiment of the present invention and is part of a developed cross-sectional view of a configuration of the reactor when cut in a cylindrical plane perpendicular to the horizontal plane through the center of the multiple spot facings 10 on the multiple susceptors 8 arranged side by side, corresponding to FIG. 7. The lamps 98, however, heat the susceptors 8 made of thin plates in the same way as in the seventh embodiment.

In FIG. 22, the susceptor 8 has a shape that approximates a right triangle with a base parallel to the horizontal plane in a cross-section cut by a plane perpendicular to both a spot facing 10 as a substrate mounting surface provided on a slope 9 and the horizontal plane. In other words, the susceptor 8 consists of two flat plates facing each other such that the narrower the distance between them the higher they are, while the one without a substrate mounting surface is a vertical surface, with only one substrate 16 being mounted on one susceptor 8.

In this configuration, although the number of the susceptors 8 needs to double to process the same number of substrates simultaneously in one reactor 3 compared to the seventh embodiment, it has the advantage of simplifying the overall configuration of the apparatus including the transfer system because of the simpler movement of the robotic arm for mounting and taking out the substrates 16. Moreover, since the distance between adjacent susceptors 8 can be made narrower, the diameter of the reactor 3 can be made smaller than the diameter of the reactor 3 in the seventh embodiment with some design efforts, potentially realizing higher area productivity.

### Ninth Embodiment

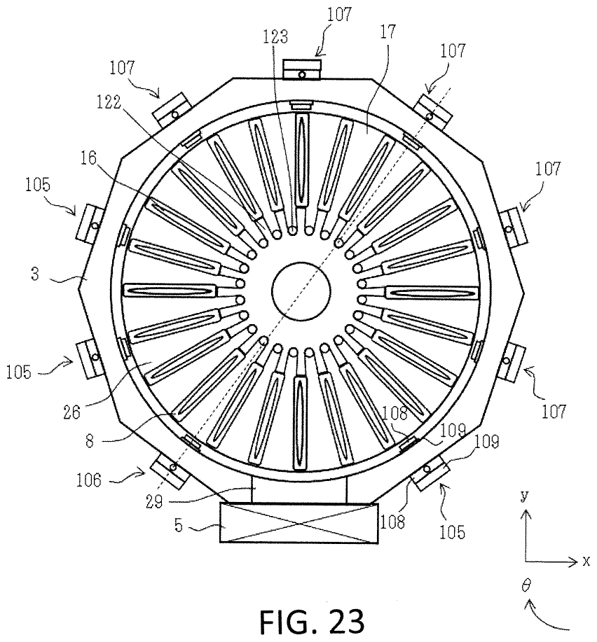

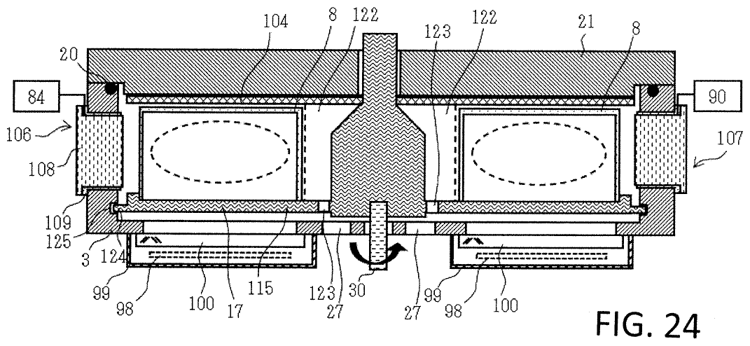

The following is a description of a ninth embodiment of the present invention, with reference to FIGS. 23 and 24.

FIG. 23 is a plan view of a configuration of a film deposition apparatus in the ninth embodiment of the present invention, viewed from the top below a top plate 104, corresponding to FIG. 19.

FIG. 24 shows the configuration of the film deposition apparatus in the ninth embodiment of the present invention and is a cross-sectional view of the configuration of the reactor when cut in a vertical plane including the dotted line in FIG. 23, corresponding to FIG. 20.

The basic operation in this embodiment is the same as in the seventh embodiment. The configuration is similar to that shown in the eighth embodiment, where only one substrate 16 is mounted on each susceptor 8, which is made of thin plates.

In FIGS. 23 and 24, the reactor 3 is a decagonal prism as a whole, but its inner wall is cylindrical in shape. The plurality of susceptors 8 is arranged side by side horizontally and radially on a susceptor holder 17 in a doughnut-shaped concave space inside the reactor 3. Each gas supply nozzle is arranged circumferentially on the side of the reactor 3 in the order of a precursor-containing gas supply nozzle 106, a purge gas supply nozzle 105, a purge gas supply nozzle 105, an oxidant-containing gas supply nozzle 107, an oxidant-containing gas supply nozzle 107, an oxidant-containing gas supply nozzles 107, an oxidant-containing gas supply nozzles 107, an oxidant-containing gas supply nozzles 107 and a purge gas supply nozzle 105 and injects each gas into the V-shaped groove space 26 between the two susceptors 8. A lid 21 is placed on top of the reactor 3 via an o-ring 20 to ensure airtightness. In other words, the film deposition process can be performed under vacuum conditions.

A wall 122 integrated with the susceptor holder 17 is provided radially between the cylindrical portion of the center of the susceptor holder 17 and each susceptor 8, outwardly from the cylindrical portion of the center of the susceptor holder 17. A number of exhaust holes 123 (rotating exhaust ports that rotate with the susceptors 8 and exhaust the space between the two susceptors 8) are provided near the bottom part of each wall 122 in the susceptor holder 17. Thus, the gases supplied to the reactor 3 are exhausted from the V-shaped groove space 26 between the two susceptors 8, through the space between the two walls 122, through the exhaust holes 123, and through the exhaust port 27.

The diameter of the susceptor holder 17 is larger than the diameter of the inner wall of the reactor 3, and its outermost part 124 is engaged in a groove 125 formed all the way around the inner wall of the reactor 3. This configuration makes the ratio of gas exhausted from the gap between the outer periphery of the susceptor holder 17 and the inner wall of the reactor 3 extremely small. Thus, most of the gases are exhausted from the V-shaped groove space 26 between the two susceptors 8, through the space between the two walls 122, through the exhaust holes 123, and then through the exhaust port 27.

### Tenth Embodiment

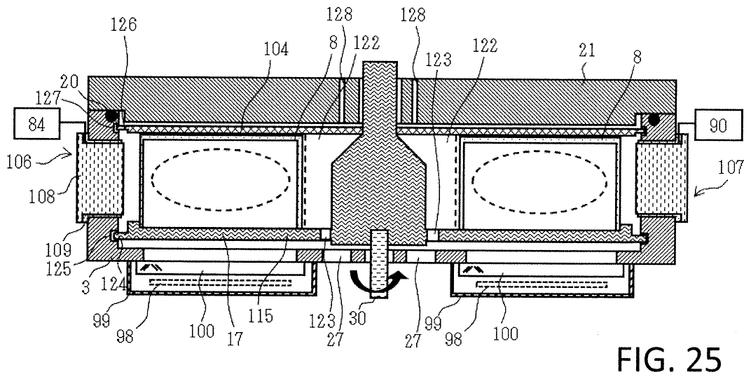

The following is a description of a tenth embodiment of the present invention, with reference to FIG. 25.

FIG. 25 shows a configuration of a film deposition apparatus in the tenth embodiment of the present invention and is a cross-sectional view of a configuration of the reactor when cut in a vertical plane including the dotted line in FIG. 23, corresponding to FIG. 24.

In FIG. 25, the diameter of the top plate 104 is larger than the diameter of the inner wall of the reactor 3, and its outermost part 126 is engaged in a groove 127 formed all the way around the inner wall of the reactor 3. A gas introduction hole 128 is provided to supply the purge gas or inert gas between the top plate 104 and the ceiling surface of the reactor 3 (bottom surface of a lid 21). This configuration prevents gases from entering through the gap between the outer periphery of the susceptor holder 17 and the inner wall of the reactor 3, making the ratio of gas mixing in the plurality of V-shaped groove spaces 26 extremely small. This even more effectively prevents different types of gases from mixing with each other through the top part of the reactor 3.

The film deposition apparatus and method described above are merely typical examples of the scope of application of the present invention, and the invention can be applied to various other fields in addition to those described above.

For example, the cases of performing the deposition method by ALD are shown as examples, although deposition by CVD or epitaxial growth may also be performed. Since the gas velocity in the V-shaped groove space 26 is larger the lower it is, the depletion of the process gas downstream is mitigated, and the difference in deposition rate between the upper and lower parts of the spot facing 10 becomes small. This effect is particularly significant in epitaxial growth.

The cases of the substrate mounting surfaces being the spot facings 10 formed on the susceptors 8 are shown as examples, although the substrate mounting surfaces may be defined by pins placed at several points around the substrate mounting surfaces to prevent a substrate from falling.

The cases of the configuration with a plasma-generating device that generates a plasma in the fan-shaped portion where a gas is injected from the oxidant-containing gas supply tube 25 and the configuration with a plasma-generating device that generates a plasma in an aperture on the side of the reactor, where the susceptors 8 rotate in the circumferential direction in the doughnut-shaped shape, are shown as examples, although a plasma-generating device generating a plasma inside the reactor may also be provided in other embodiments. Also in these cases, the process can be performed at lower temperatures and the films can be densified by generating a plasma from the oxidant-containing gas.

The cases of generating a plasma 45 in the space between the shower plate 18 and the susceptors 8 by supplying high-frequency power to the electrode 42 and of generating inductively coupled plasma by supplying high-frequency power to the coil 118 are shown as examples of using a plasma-generating device, although various methods of generating a plasma, such as a method using pulsed power or a method using microwaves, may be applied. The plasma-generating device is preferably installed in the upper stream of the gas flow than the substrate mounting surfaces. This makes the use of active particles, such as ions and radicals, more efficient.

The various configurations of the present invention enable various film deposition processes. For example, it is effective to apply to the manufacturing of electronic devices such as semiconductors, flat panel displays, solar cells and light-emitting diodes. In particular, it can be used in many processes, including the double patterning process, high-k/metal gate formation, top and bottom electrode formation for DRAM capacitors using TiN or Ru, gate electrode sidewall formation using SiN and barrier seed formation in contact holes and through holes for semiconductor integrated circuit manufacturing, as well as high-k dielectric and charge trap film formation for NAND flash memory. It can also be used in the formation of ITO films and passivation films for flat panel displays, LEDs and solar cells.

### INDUSTRIAL APPLICABILITY

As described above, the present invention can be used to manufacture various electronic devices and is effective to apply to the manufacturing of electronic devices such as semiconductors, flat panel displays, solar cells and light-emitting diodes. In particular, it can be used in many processes, including the double patterning process, high-k/metal gate formation, top and bottom electrode formation for DRAM capacitors using TiN or Ru, gate electrode sidewall formation using SiN and barrier seed formation in contact holes and through holes for semiconductor integrated circuit manufacturing, as well as high-k dielectric and charge trap film formation for NAND flash memory. The present invention is also useful in the formation of ITO films and passivation films for flat panel displays, LEDs and solar cells.

### REFERENCE SIGNS LIST

3 reactor
8 susceptor
9 slope
10 spot facing
11 end face
15 top surface of susceptor
17 susceptor holder
18 shower plate
19 gas outlet holes
20 o-ring
21 lid
22 purge gas supply tube
23 precursor-containing gas supply tube
24 purge gas supply tube
25 oxidant-containing gas supply tube
29 gate opening

1. A film deposition apparatus comprising:
a reactor;
a plurality of substrate mounting surfaces inclined with respect to a vertical plane;
a susceptor comprising the substrate mounting surface,
wherein two of the plurality of substrate mounting surfaces face each other such that a distance between the two of the plurality of substrate mounting surfaces becomes wider the higher they are; and
a gas nozzle that injects a gas downward between the two substrate mounting surfaces,
wherein the gas nozzle has an aperture with a larger penetrating area toward a center of the substrate mounting surfaces than toward a periphery of the substrate mounting surfaces.

2. A film deposition apparatus comprising:
a reactor;
a plurality of substrate mounting surfaces inclined with respect to a vertical plane;
a susceptor comprising the substrate mounting surface,
wherein two of the plurality of substrate mounting surfaces face each other such that a distance between the two of the plurality of substrate mounting surfaces becomes wider the higher they are; a gas nozzle that injects a gas downward between the two substrate mounting surfaces; and
a moving mechanism moving the susceptor horizontally in the reactor,
wherein the gas nozzle is divided into a plurality of gas nozzle groups in a direction of movement of the moving mechanism, each of the gas nozzle groups is capable of injecting a different type of gas,
a plurality of susceptors is provided and arranged side by side,
the moving mechanism moves the susceptors in a direction in which the plurality of susceptors is arranged,
the plurality of susceptors is arranged in a rectangular space in the reactor, and
the moving mechanism is a sliding mechanism moving the plurality of susceptors in a linear direction in the rectangular space.

3. A film deposition apparatus comprising:
a reactor;
a plurality of substrate mounting surfaces inclined with respect to a vertical plane;
a susceptor comprising the substrate mounting surface,
wherein two of the plurality of substrate mounting surfaces face each other such that a distance between the two of the plurality of substrate mounting surfaces becomes wider the higher they are; and
a moving mechanism moving the susceptor horizontally in the reactor,
wherein a gas nozzle divided into a plurality of gas nozzle groups in a direction of movement of the moving mechanism injects a different type of gas from each of the gas nozzle groups,
each of the gas nozzle groups is capable of injecting either a precursor-containing gas, a purge gas or a reactant-containing gas, and
a gas nozzle group injecting the purge gas is arranged between a gas nozzle group injecting the precursor-containing gas and a gas nozzle group injecting the reactant-containing gas.

4. A film deposition method comprising the steps of:
moving and mounting a substrate from outside a reactor on a plurality of substrate mounting surfaces provided in the reactor that is inclined with respect to a vertical plane;
exhausting gas from the reactor while supplying a gas into the reactor; and
moving the substrate from the substrate mounting surface to an outside of the reactor to remove the substrate from the reactor,
wherein two of the plurality of substrate mounting surfaces face each other such that a distance between the two of the plurality of substrate mounting surfaces becomes wider the higher they are,
the substrate mounting surface is moved horizontally in the reactor by a moving mechanism moving the substrate mounting surface horizontally in the reactor,
a gas nozzle divided into a plurality of gas nozzle groups in a direction of movement of the moving mechanism injects a different type of gas from each of the gas nozzle groups,
the plurality of substrate mounting surfaces is arranged in a rectangular space in the reactor, and
the plurality of substrate mounting surfaces is moved in a linear direction in the rectangular space.

5. A film deposition method comprising the steps of:
moving and mounting a substrate from outside a reactor on a plurality of substrate mounting surfaces provided in the reactor that is inclined with respect to a vertical plane;
exhausting gas from the reactor while supplying a gas into the reactor; and
moving the substrate from the substrate mounting surface to an outside of the reactor to remove the substrate from the reactor,
wherein two of the plurality of substrate mounting surfaces face each other such that a distance between the two of the plurality of substrate mounting surfaces becomes wider the higher they are,
the substrate mounting surface is moved horizontally in the reactor by a moving mechanism moving the substrate mounting surface horizontally in the reactor,
a gas nozzle divided into a plurality of gas nozzle groups in a direction of movement of the moving mechanism injects a different type of gas from each of the gas nozzle groups,
each of the gas nozzle groups is capable of injecting either a precursor-containing gas, a purge gas or a reactant-containing gas, and
a gas nozzle group injecting the purge gas is arranged between a gas nozzle group injecting the precursor-containing gas and a gas nozzle group injecting the reactant-containing gas.

6. A film deposition apparatus comprising:
a reactor;
a plurality of susceptors comprising a substrate mounting surface inclined with respect to a vertical plane in the reactor,
wherein the plurality of susceptors is arranged horizontally, and
two of the plurality of susceptors face each other such that a distance between the two of the plurality of substrate mounting surfaces becomes wider the higher they are; and
a moving mechanism moving the susceptor horizontally in the reactor,
wherein a gas nozzle divided into a plurality of gas nozzle groups in a direction of movement of the moving mechanism injects a different type of gas from each of the gas nozzle groups,
each of the gas nozzle groups is capable of injecting either a precursor-containing gas, a purge gas or a reactant-containing gas, and
a gas nozzle group injecting the purge gas is arranged between a gas nozzle group injecting the precursor-containing gas and a gas nozzle group injecting the reactant-containing gas.

7. The film deposition apparatus according to claim 1, wherein the plurality of susceptors is arranged radially in a doughnut-shaped space in the reactor,
further comprising a rotating mechanism rotating the plurality of susceptors in a circumferential direction in the doughnut-shaped space.

8. The film deposition apparatus according to claim 7, wherein the plurality of susceptors is arranged on a susceptor holder,
a diameter of the susceptor holder is larger than a diameter of an inner wall of the reactor, and
an outermost part of the susceptor holder is engaged in a groove formed all the way around the inner wall of the reactor.

9. The film deposition apparatus according to claim 7, wherein the plurality of susceptors is arranged on a susceptor holder,
further comprising a top plate integrated with the susceptor holder above the plurality of susceptors,
wherein the top plate rotates together with the susceptors and the susceptor holder.

10. The film deposition apparatus according to claim 9, wherein a diameter of the top plate is larger than a diameter of the inner wall of the reactor,
an outermost part of the top plate is engaged in a groove formed all the way around the inner wall of the reactor, and
a purge gas or an inert gas is supplied between the top plate and a ceiling surface of the reactor.

11. The film deposition apparatus according to claim 7, further comprising a rotating exhaust port rotating together with the susceptors and exhausting a space between the two susceptors.

12. A film deposition method comprising the steps of:
moving and mounting a substrate from outside a reactor on a substrate mounting surface provided on a plurality of susceptors comprising the substrate mounting surface inclined with respect to a vertical plane in the reactor;
exhausting gas from the reactor while supplying a gas into the reactor; and
moving the substrate from the substrate mounting surface to an outside of the reactor to remove the substrate from the reactor,
wherein the plurality of susceptors is arranged horizontally,
two of the plurality of susceptors face each other such that a distance between the two of the plurality of substrate mounting surfaces becomes wider the higher they are,
the substrate mounting surface is moved horizontally in the reactor by a moving mechanism moving the substrate mounting surface horizontally in the reactor,
a gas nozzle divided into a plurality of gas nozzle groups in a direction of movement of the moving mechanism injects a different type of gas from each of the gas nozzle groups,
each of the gas nozzle groups is capable of injecting either a precursor-containing gas, a purge gas or a reactant-containing gas, and
a gas nozzle group injecting the purge gas is arranged between a gas nozzle group injecting the precursor-containing gas and a gas nozzle group injecting the reactant-containing gas.

13. The film deposition method according to claim 4, wherein the plurality of substrate mounting surfaces is arranged radially in a doughnut-shaped space in the reactor, and
the plurality of substrate mounting surfaces is rotated in a circumferential direction in the doughnut-shaped space.
